(19) United States
(12) Patent Application Publication
(10) Pub. No.: US 2024/0096955 A1
(43) Pub. Date: Mar. 21, 2024

(54) INTEGRATED CIRCUIT DEVICE INCLUDING MULTI-CHANNEL TRANSISTOR

(71) Applicant: Samsung Electronics Co., Ltd., Suwon-si (KR)

(72) Inventors: Myunggil KANG, Suwon-si (KR); Beomjin Park, Suwon-si (KR); Dongwon Kim, Suwon-si (KR)

(73) Assignee: Samsung Electronics Co., Ltd., Suwon-si (KR)

(21) Appl. No.: 18/367,852

(22) Filed: Sep. 13, 2023

(30) Foreign Application Priority Data
Sep. 20, 2022 (KR) 10-2022-0118694

(51) Int. Cl. H01L 29/06; H01L 27/092; H01L 29/423; H01L 29/66; H01L 29/775; H01L 29/786

(52) U.S. Cl. CPC H01L 29/0673; H01L 27/092; H01L 29/42392; H01L 29/66545; H01L 29/775; H01L 29/78696

(57) ABSTRACT

In some embodiments, an integrated circuit device includes a substrate, a fin-type active region on the substrate that extends in a first direction, a plurality of semiconductor patterns spaced apart from an upper surface of the fin-type active region and include a channel region, a gate electrode, and a gate cut insulating pattern. The gate electrode extends in a second direction on the fin-type active region and is disposed between the plurality of semiconductor patterns. The gate electrode includes a first sidewall extending in the second direction and a second sidewall extending in the first direction. The gate cut insulating pattern is on a second sidewall of the gate electrode. An upper portion of the gate cut insulating pattern is wider in the second direction than a lower portion of the gate cut insulating pattern. A portion of a sidewall of the gate cut insulating pattern is curved.

### CROSS-REFERENCE TO RELATED APPLICATION

This application claims benefit of priority under 35 U.S.C. § 119 to Korean Patent Application No. 10-2022-0118694, filed on Sep. 20, 2022, in the Korean Intellectual Property Office, the disclosure of which is incorporated by reference herein in its entirety.

### BACKGROUND

### 1. Field

The present disclosure relates generally to an integrated circuit device, and more particularly, to an integrated circuit device including a field effect transistor.

### 2. Description of Related Art

To meet an increasing demand on related integrated circuits by electronics technology, an integration level of related integrated circuit devices may be increased and/or the related integrated circuit devices may be further downscaled. However, the downscaling of the integrated circuit devices may lead to a short channel effect on transistors implemented by the downscaled integrated circuit devices, which may deteriorate a reliability of the related integrated circuit devices. In order to reduce the short channel effect, integrated circuit devices including a gate-all-around (GAA) transistor structure have been proposed, such as, but not limited to, a nanosheet type transistor.

### SUMMARY

The present disclosure provides an integrated circuit device capable of reducing or preventing defects in a sacrificial gate electrode removal process.

According to an aspect of the present disclosure, an integrated circuit device is provided. The integrated circuit device includes a substrate, a fin-type active region on the substrate and extending in a first direction, a plurality of semiconductor patterns spaced apart from an upper surface of the fin-type active region and including a channel region, a gate electrode extending in a second direction on the fin-type active region, and a gate cut insulating pattern. The gate electrode is disposed between the plurality of semiconductor patterns, and includes a first sidewall extending in the second direction and a second sidewall extending in the first direction. The second direction intersects with the first direction. The gate cut insulating pattern is on the second sidewall of the gate electrode. An upper portion of the gate cut insulating pattern has a first width in the second direction. A lower portion of the gate cut insulating pattern has a second width in the second direction. The second width is smaller than the first width. A portion of a sidewall of the gate cut insulating pattern is curved.

According to an aspect of the present disclosure, an integrated circuit device is provided. The integrated circuit device includes a substrate, a fin-type active region on the substrate and extending in a first direction, a plurality of semiconductor patterns spaced apart from an upper surface of the fin-type active region and including a channel region, a gate electrode extending in a second direction on the fin-type active region, and a gate cut insulating pattern. The gate electrode is disposed between the plurality of semiconductor patterns, and includes a shoulder portion extending outwardly in the second direction. The second direction intersects with the first direction. The gate cut insulating pattern is disposed on a first sidewall of the gate electrode, and includes a stepped portion conforming to a shape of the shoulder portion.

According to an aspect of the present disclosure, an integrated circuit device is provided. The integrated circuit device includes a substrate, a fin-type active region on the substrate and extending from a substrate in a first direction, a device isolation layer disposed on the substrate and disposed on a sidewall of the fin-type active region, a plurality of semiconductor patterns spaced apart from an upper surface of the fin-type active region and comprising a channel region, a gate electrode extending in a second direction on the fin-type active region, a gate insulating layer, a gate cut insulating pattern, and an inter-gate insulating layer. The gate electrode is disposed between the plurality of semiconductor patterns, and includes a shoulder portion extending outwardly in the second direction. The second direction intersects with the first direction. The gate insulating layer surrounds a first sidewall extending in the second direction of the gate electrode, a second sidewall extending in the first direction of the gate electrode, and a bottom surface of the gate electrode. The gate cut insulating pattern is disposed on the second sidewall of the gate electrode, and includes a stepped portion conforming to a shape of the shoulder portion of the gate electrode. A portion of the gate insulating layer is disposed between the stepped portion and the shoulder portion of the gate electrode. The inter-gate insulating layer is disposed on the substrate, on the first sidewall of the gate electrode, and on a sidewall of the gate cut insulating pattern.

Additional aspects will be set forth in part in the description which follows and, in part, will be apparent from the description, or may be learned by practice of the presented embodiments.

### BRIEF DESCRIPTION OF DRAWINGS

The above and other aspects, features, and advantages of certain embodiments of the present disclosure will be more apparent from the following detailed description taken in conjunction with the accompanying drawings in which:

FIG. 1 is a schematic layout diagram illustrating an integrated circuit device, according to some embodiments;

FIG. 2 is an enlarged layout diagram of part II of FIG. 1, according to some embodiments;

FIG. 3 is a cross-sectional view taken along line A1-A1′ of FIG. 2, according to some embodiments;

FIG. 4 is a cross-sectional view taken along line B1-B1′ of FIG. 2, according to some embodiments;

FIG. 5 is a cross-sectional view taken along line B2-B2′ of FIG. 2, according to some embodiments;

FIG. 6 is an enlarged view of a part CX1 of FIG. 4, according to some embodiments;

FIG. 7 is a cross-sectional view illustrating an integrated circuit device, according to some embodiments;

FIG. 8 is a cross-sectional view illustrating an integrated circuit device, according to some embodiments;

FIG. 9 is a cross-sectional view illustrating an integrated circuit device, according to some embodiments;

FIG. 10 is a cross-sectional view illustrating an integrated circuit device, according to some embodiments;

FIG. 11 is a cross-sectional view illustrating an integrated circuit device, according to some embodiments;

FIG. 12 is a cross-sectional view illustrating an integrated circuit device, according to some embodiments;

FIG. 13 is a cross-sectional view illustrating an integrated circuit device, according to some embodiments;

FIG. 14 is a cross-sectional view illustrating an integrated circuit device, according to some embodiments;

FIG. 15 is a layout diagram illustrating an integrated circuit device, according to some embodiments;

FIG. 16 is a cross-sectional view taken along line B1-B1′ in FIG. 15, according to some embodiments;

FIG. 17 is a cross-sectional view taken along line B2-B2′ in FIG. 15, according to some embodiments;

FIGS. 18, 19A, 19B, 19C, 20A, 20B, 20C, 21A, 21B, 22, 23, 24, 25, 26A, 26B, 27, 28A, 28B, 29A, 29B, and 29C are cross-sectional views illustrating a manufacturing method of an integrated circuit device, according to some embodiments;

FIGS. 30 and 31 are cross-sectional views illustrating a manufacturing method of an integrated circuit device, according to some embodiments; and

FIGS. 32 and 33 are cross-sectional views illustrating a manufacturing method of an integrated circuit device, according to some embodiments.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art will recognize that various changes and modifications of the embodiments described herein can be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, etc. may be replaced with terms, such as “first,” “second,” third” to be used to describe relative positions of elements. The terms “first,” “second,” third” may be used to described various elements but the elements are not limited by the terms and a “first element” may be referred to as a “second element”. Alternatively or additionally, the terms “first”, “second”, “third”, etc. may be used to distinguish components from each other and do not limit the present disclosure. For example, the terms “first”, “second”, “third”, etc. may not necessarily involve an order or a numerical meaning of any form.

As used herein, each of the terms “Al₂O₃”, “CoSi”, “GaAs”, “HfO₂”, “HfSiO”, “InAs”, “InP”, “MoS₂”, “NiSi”, “SiC”, “SiGe”, “SiON”, “TaC”, “TaCN”, “TaN”, “TaSiN”, “TiAl”, “TiAlN”, “TiN”, “WN”, “ZrO₂”, and the like may refer to a material made of elements included in each of the terms and is not a chemical formula representing a stoichiometric relationship.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment.

Hereinafter, embodiments of the present disclosure are described in detail with reference to the accompanying drawings.

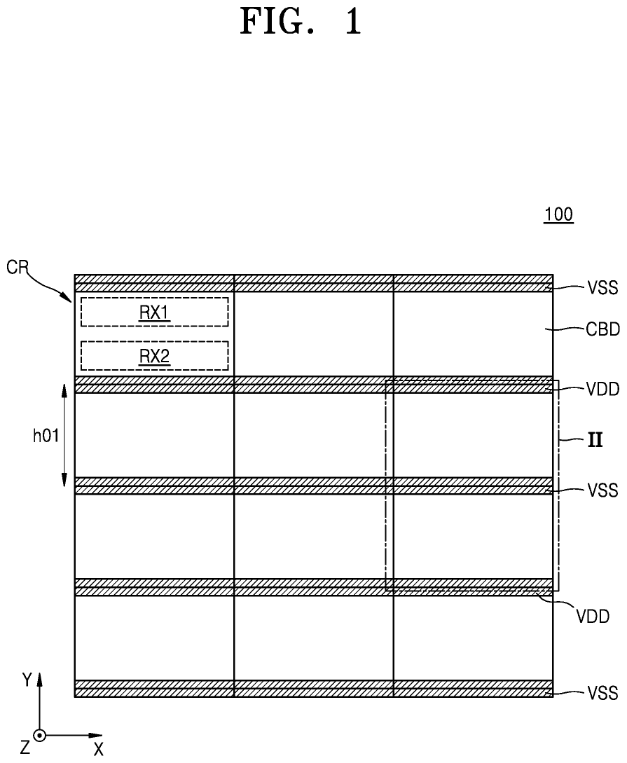

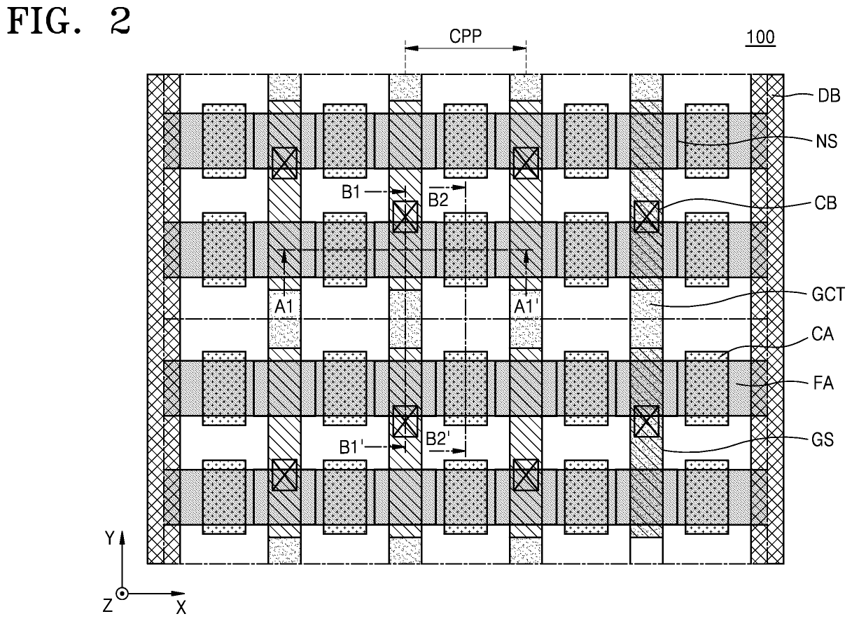

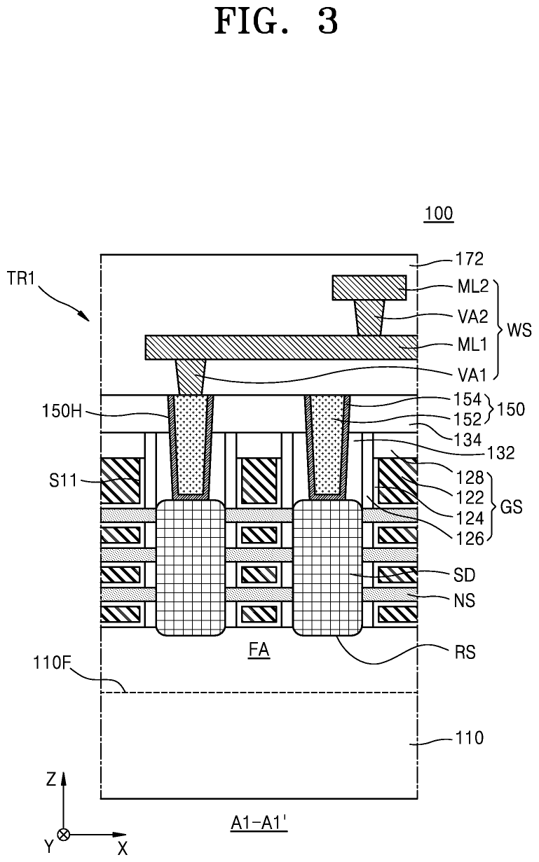

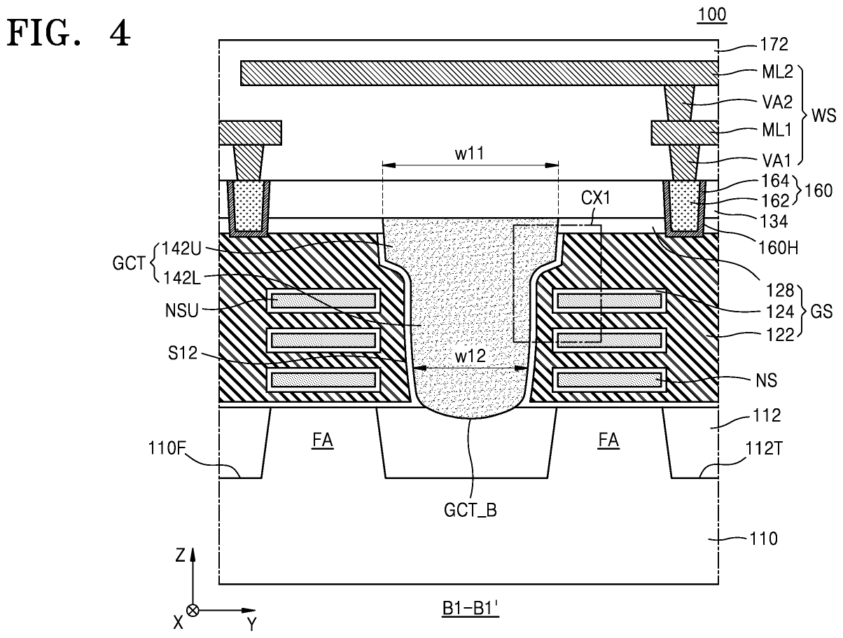

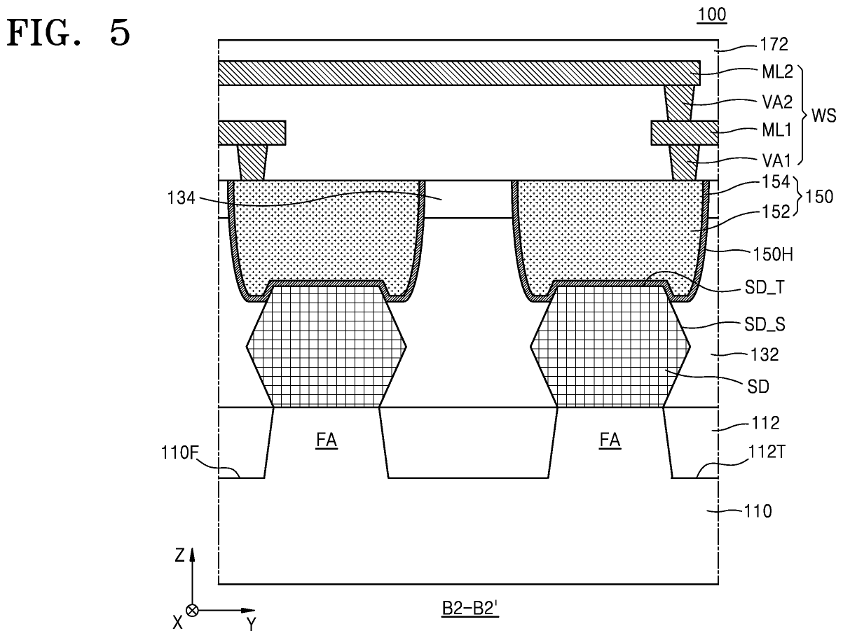

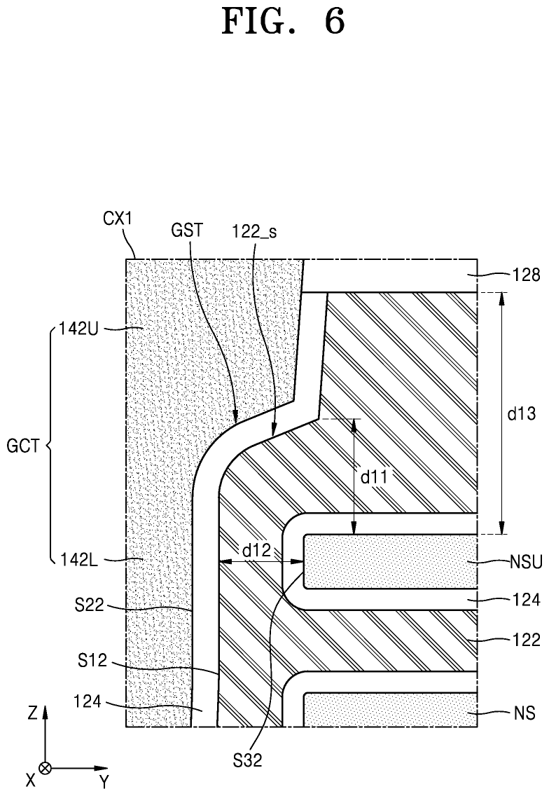

FIG. 1 is a schematic layout diagram illustrating an integrated circuit device 100, according to some embodiments. FIG. 2 is an enlarged layout diagram of part II of FIG. 1, according to some embodiments. FIG. 3 is a cross-sectional view taken along line A1-A1′ of FIG. 2, according to some embodiments. FIG. 4 is a cross-sectional view taken along line B1-B1′of FIG. 2, according to some embodiments. FIG. 5 is a cross-sectional view taken along line B2-B2′ of FIG. 2. FIG. 6 is an enlarged view of a part CX1 of FIG. 4, according to some embodiments.

Referring to FIGS. 1 to 6, the integrated circuit device 100 may include a plurality of cells CR disposed on a first surface 110F of a substrate 110. The plurality of cells CR may be arranged in a matrix form in a first horizontal direction X and a second horizontal direction Y. The first horizontal direction X and the second horizontal direction Y may be parallel to the first surface 110F of the substrate 110. Each of the plurality of cells CR may include a region in which various types of logic cells included in a logic circuit are disposed.

In the embodiments shown in FIGS. 1 to 6, the integrated circuit device 100 may include a logic cell including, but not limited to, a gate-all-around (GAA) type field-effect transistor (FET) such as a multi-bridge channel FET (e.g., MBCFET™) device. However, the present disclosure is not limited in this regard. For example, the integrated circuit device 100 may include, but not be limited to, a planar FET device and a fin field-effect transistor (finFET) device, a FET device based on a two-dimensional (2D) material such as, but not limited to, a molybdenum disulfide (MoS₂) semiconductor gate electrode, and the like.

On the first surface 110F of the substrate 110, a plurality of ground lines VSS and a plurality of power lines VDD may extend in the first horizontal direction X and may be alternately spaced in the second horizontal direction Y intersecting with the first horizontal direction X. Accordingly, a cell boundary CBD of one cell CR in the second horizontal direction Y may be disposed to overlap one ground line VSS and one power line VDD. The cell CR in which the cell boundary CBD overlaps one ground line VSS and one power supply line VDD adjacent thereto, may be referred to as a single height cell. The cell CR, which is a single height cell, may have a first height h01 in the second horizontal direction Y.

Cell boundaries CBD of the plurality of cells CR in the first horizontal direction X may be disposed to overlap isolation structures DB. The isolation structures DB may extend in the second horizontal direction Y, and may electrically insulate one cell CR from another adjacent cell CR. The isolation structures DB may include an insulating material.

As shown in FIG. 1, the substrate 110 may include a first active region RX1 and a second active region RX2 spaced apart in the second horizontal direction Y. For example, each of the plurality of cells CR may be disposed to include the first active region RX1 and the second active region RX2. Each of the plurality of cells CR may include a transistor TR1 formed on each of the first and second active regions RX1 and RX2. For example, the transistor TR1 disposed on the first active region RX1 may be a p-channel metal-oxide semiconductor (PMOS) transistor, and the transistor TR1 disposed on the second active region RX2 may be an n-channel metal-oxide semiconductor (NMOS) transistor.

In some embodiments, the substrate 110 may include a group IV semiconductor such as silicon (Si) or germanium (Ge), a group IV-IV compound semiconductor such as silicon germanium (SiGe) or silicon carbide (SiC), or a group III-V compound semiconductor such as gallium arsenide (GaAs), indium arsenide (InAs), or indium phosphide (InP).

In some embodiments, a plurality of fin-type active regions FA may protrude from the first surface 110F of the substrate 110 and extend in the first horizontal direction X. In some optional or additional embodiments, one fin-type active region FA may be disposed on the first active region RX1 and one fin-type active region FA may be disposed on the second active region RX2.

An isolation layer 112 may be disposed on the first surface 110F of the substrate 110 to cover a lower portion of a sidewall of the fin-type active region FA. The device isolation layer 112 may fill an inside of a device isolation trench 112T extending from the first surface 110F of the substrate 110 into the substrate 110, and may have, for example, a double layer structure of an interfacial layer (not shown) and a buried insulating layer (not shown).

In some embodiments, a plurality of semiconductor patterns NS may be spaced apart from each other in a vertical direction Z on the fin-type active region FA. Each of the plurality of semiconductor patterns NS may include a group IV semiconductor such as silicon (Si) or germanium (Ge), a group IV-IV compound semiconductor such as silicon germanium (SiGe) or silicon carbide (SiC), or a group III-V compound semiconductor such as gallium arsenide (GaAs), indium arsenide (InAs), or indium phosphide (InP). Each of the plurality of semiconductor patterns NS may have a relatively large width in the second horizontal direction Y and a relatively small thickness in the vertical direction Z. Each of the plurality of semiconductor patterns NS may have, for example, a nanosheet shape. For example, in some embodiments, each of the plurality of semiconductor patterns NS may have a width in the range of approximately 5 nanometers (nm) to approximately 100 nm in the second horizontal direction Y, and/or may have a thickness in the range of approximately 1 nm to approximately 10 nm in the vertical direction Z. However, the present disclosure is not limited in this regard. For example, each of the plurality of semiconductor patterns NS may have different widths and/or thicknesses without departing from the scope of the present disclosure. Each of the plurality of semiconductor patterns NS may form a channel layer or a channel structure of the transistor TR1.

The plurality of gate structures GS may extend in the second horizontal direction Y to surround the plurality of semiconductor patterns NS, and may be spaced apart by a first gate space CPP in the first horizontal direction X. Each of the plurality of gate structures GS may include a gate electrode 122, a gate insulating layer 124, a gate spacer 126, and a gate capping layer 128. For example, the gate electrodes 122 may extend in the second horizontal direction Y so as to surround the plurality of semiconductor patterns NS on the fin-type active region FA. According to an embodiment, the gate insulating layers 124 may be disposed between the gate electrode 122 and the fin-type active region FA, between the gate electrode 122 and the device isolation layer 112, and between the gate electrode 122 and each semiconductor pattern NS. The gate spacers 126 may be disposed on both sidewalls of the gate electrode 122. The gate capping layer 128 may extend in the second horizontal direction Y on the gate electrode 122 and the gate insulating layer 124.

In some embodiments, the gate electrode 122 may include, but not be limited to, a doped polysilicon, a metal, a conductive metal nitride, a conductive metal carbide, a conductive metal silicide, or a combination thereof. For example, the gate electrode 122 may include, but not be limited to, aluminum (Al), copper (Cu), titanium (Ti), tantalum (Ta), tungsten (W), molybdenum (Mo), tantalum nitride (TaN), nickel silicide (NiSi), cobalt silicide (CoSi), titanium nitride (TiN), tungsten nitride (WN), titanium aluminide (TiAl), titanium aluminum carbide (TiAlC), titanium aluminum nitride (TiAlN), tantalum carbonitride (TaCN), tantalum carbide (TaC), tantalum silicon nitride (TaSiN), or a combination thereof.

In some embodiments, the gate electrode 122 may include a work function metal-containing layer (not shown) and a gap-fill metal layer (not shown). The work function metal-containing layer may include, but not be limited to, at least one metal of titanium (Ti), tungsten (W), ruthenium (Ru), niobium (Nb), molybdenum (Mo), hafnium (Hf), nickel (Ni), cobalt (Co), platinum (Pt), ytterbium (Yb), terbium (Tb), dysprosium (Dy), erbium (Er), or palladium (Pd). The gap-fill metal layer may include, but not be limited to, a tungsten (W) layer or an aluminum (Al) layer. In some embodiments, the gate electrode 122 may have a TiAlC/TiN/W stack structure, a TiN/TaN/TiAlC/TiN/W stack structure, or a TiN/TaN/TiN/TiAlC/TiN/W stack structure. However, the present disclosure is not limited in this regard. For example, the gate electrode 122 may have different stack structures comprising different sequences of similar materials without departing from the scope of the present disclosure.

In some embodiments, the gate insulating layer 124 may include, but not be limited to, a silicon oxide layer (SiOₓ), a silicon oxynitride (SiOₓN_{y}) layer, a high-k dielectric layer having a dielectric constant higher than the silicon oxide layer, or a combination thereof. The high-k dielectric layer may include, but not be limited to, a metal oxide or a metal oxynitride. For example, the high-k dielectric layer usable as the gate insulating layer 124 may include, but not be limited to, hafnium oxide (HfO₂), hafnium silicate (HfSiO), hafnium silicon oxynitride (HfSiON), hafnium tantalum oxide (HMO), hafnium titanium oxide (HfTiO), hafnium zirconium oxide (HfZrO), zirconium oxide (ZrO₂), aluminum oxide (Al₂O₃), or a combination thereof.

In some embodiments, the gate spacer 126 may include, but not be limited to, silicon oxide (SiOₓ), silicon nitride (SiNₓ), silicon oxynitride (SiOₓN_{y}), silicon carbonitride (SiCₓN_{y}), silicon oxycarbonitride (SiOₓC_{y}N_{z}), or a combination thereof. In some embodiments, the gate capping layer 128 may include, but not be limited to, a silicon nitride or a silicon oxynitride (SiOₓN_{y}).

The gate electrode 122 may have two first sidewalls S11 spaced apart in the first horizontal direction X and extending in the second horizontal direction Y. Alternatively or additionally, the gate electrode 122 may have two second sidewalls S12 spaced apart in the second horizontal direction Y and extending in the first horizontal direction X. For example, the first sidewall S11 of the gate electrode 122 may face the gate spacer 126 with the gate insulating layer 124 disposed therebetween, and may be surrounded by the gate spacer 126.

A gate cut insulating pattern GCT may be disposed on the second sidewall S12 of the gate electrode 122. The gate cut insulating pattern GCT may be disposed between two gate electrodes 122 disposed adjacent to each other in the second horizontal direction Y. As shown in FIGS. 4 and 6, at least a part of a sidewall S22 of the gate cut insulating pattern GCT may be curved. In some embodiments, the gate cut insulating pattern GCT may include, but not be limited to, silicon nitride (SiNₓ).

The gate cut insulating pattern GCT may have an upper surface disposed at the same level as the upper surface of the gate capping layer 128 and may have a bottom surface GCT_B disposed at a level lower than the bottom surface of the gate electrode 122. For example, as shown in FIG. 4, the bottom surface GCT_B of the gate cut insulating pattern GCT may be disposed on the device isolation layer 112 and may directly contact the upper surface of the device isolation layer 112. In an optional or additional embodiment, the bottom surface GCT_B of the gate cut insulating pattern GCT may contact the first surface 110F of the substrate 110. In another optional or additional embodiment, the gate cut insulating pattern GCT may be formed through the first surface 110F of the substrate 110, and the bottom surface GCT_B of the gate cut insulating pattern GCT may be at a level lower than the first surface 110F of the substrate 110.

In some embodiments, the gate cut insulating pattern GCT may include an upper portion 142U and a lower portion 142L, the upper portion 142U may have a first width w11 in the second horizontal direction Y, and the lower portion 142L may have a second width w12 less than the first width w11 in the second horizontal direction Y. The first width w11 of the upper portion 142U of the gate cut insulating pattern GCT may refer to a width measured at a vertical level higher than an uppermost semiconductor pattern NSU (as shown in FIG. 4). For example, the first width w11 may refer to a width at the same level as the upper surface of the gate electrode 122. The second width w12 of the lower portion 142L of the gate cut insulating pattern GCT may refer to a width measured at a vertical level lower than the uppermost semiconductor pattern NSU (as shown in FIG. 4). For example, the second width w12 may refer to a width at the same level as upper surfaces of the remaining semiconductor patterns NS except for the uppermost semiconductor pattern NSU.

The second sidewall S12 of the gate electrode 122 may include a shoulder portion 122_s corresponding to at least a part of the sidewall S22 of the gate cut insulating pattern GCT. The shoulder portion 122_s may refer to a part of the second sidewall S12 of the gate electrode 122 that protrudes outwardly. The shoulder portion 122_s may be positioned to face a part of the sidewall S22 positioned on the boundary between the upper portion 142U and the lower portion 142L of the gate cut insulating pattern GCT. On the boundary between the upper portion 142U and the lower portion 142L of the gate cut insulating pattern GCT, a stepped portion GST may be defined by a relatively sharp width difference between the upper portion 142U and the lower portion 142L. The shoulder portion 122_s of the second sidewall S12 of the gate electrode 122 may be disposed adjacent to the stepped portion GST.

In some embodiments, as shown in FIG. 6, the uppermost semiconductor pattern NSU may include a first side surface S32 facing the gate cut insulating pattern GCT. A first distance d11 between the upper surface of the uppermost semiconductor pattern NSU and the shoulder portion 122_s in the vertical direction Z may be the same as or similar to a second distance d12 between the first side surface S32 of the uppermost semiconductor pattern NSU and the shoulder portion 122_s in the second horizontal direction Y. In some optional or additional embodiments, the first distance d11 between the upper surface of the uppermost semiconductor pattern NSU and the shoulder portion 122_s in the vertical direction Z may be in the range of approximately 80% to approximately 120% of the second distance d12 between the first side surface S32 of the uppermost semiconductor pattern NSU and the shoulder portion 122_s in the second horizontal direction Y. In other optional or additional embodiments, the second distance d12 may be in the range of approximately 5 nm to approximately 15 nm. However, the present disclosure is not limited in this regard. Alternatively or additionally, a third distance d13 between the upper surface of the uppermost semiconductor pattern NSU and the upper surface of the gate electrode 122 in the vertical direction Z may be greater than the first distance d11 between the upper surface of the uppermost semiconductor pattern NSU and the shoulder portion 122_s in the vertical direction Z.

In some embodiments, a part of the gate insulating layer 124 disposed between the bottom surface of the gate electrode 122 and the upper surface of the fin-type active region FA may extend between the second sidewall S12 of the gate electrode 122 and the sidewall S22 of the gate cut insulating pattern GCT in the vertical direction Z. A part of the gate insulating layer 124 disposed between the second sidewall S12 of the gate electrode 122 and the sidewall S22 of the gate cut insulating pattern GCT may be disposed to conformally cover the stepped portion GST and the shoulder portion 122_s. Alternatively or additionally, the gate insulating layer 124 may be conformally disposed on a sidewall of the upper portion 142U and a sidewall of the lower portion 142L of the gate cut insulating pattern GCT, and the gate electrode 122 may not be in direct contact with the gate cut insulating pattern GCT.

Recesses RS extending into the fin-type active region FA may be formed on both sides of the gate structure GS, and a source/drain region SD may be formed inside the recess RS. The source/drain region SD may be formed in the recess RS and may be connected to both ends of each of the plurality of semiconductor patterns NS. The source/drain region SD may have an uppermost surface SD_T disposed at a higher level than the upper surface of the uppermost semiconductor pattern NSU. As shown in FIG. 5, the source/drain region SD may have a plurality of inclined sidewalls SD_S. Alternatively or additionally, the source/drain region SD may have a vertical cross-sectional shape such as, but not limited to, a hexagon, a pentagon, a rhombus, or a polygon with rounded corners.

In some embodiments, the source/drain region SD may include, but not be limited to, a doped silicon germanium (SiGe) layer, a doped germanium (Ge) layer, a doped silicon carbide (SiC) layer, a doped indium gallium arsenic (InGaAs layer), or a combination thereof. The recesses RS may formed by removing parts of the semiconductor patterns NS on both sides of the gate structure GS, and the source/drain region SD may be formed by growing a semiconductor layer filling the inside of the recess RS by an epitaxial growth process. In some embodiments, the source/drain region SD may include a plurality of semiconductor layers having different compositions. For example, the source/drain region SD may include a lower semiconductor layer (not shown), an upper semiconductor layer (not shown), and a capping semiconductor layer (not shown) sequentially filling the recess RS. For example, the lower semiconductor layer, the upper semiconductor layer, and the capping semiconductor layer may each include silicon carbide (SiC) and have different contents of silicon (Si) and carbon (C).

An inter-gate insulating layer 132 may be formed between the gate structures GS to cover the source/drain regions SD. Alternatively or additionally, the inter-gate insulating layer 132 may be disposed on sidewalls of the gate cut insulating pattern GCT spaced apart from each other in the first horizontal direction X. For example, the upper surface of the inter-gate insulating layer 132 may be disposed at the same level as the upper surface of the gate structure GS (e.g., the upper surface of the gate capping layer 128) and the upper surface of the gate cut insulating layer GCT.

An upper insulating layer 134 may be disposed on the inter-gate insulating layer 132, the gate structure GS, and the gate cut insulating pattern GCT. The inter-gate insulating layer 132 and the upper insulating layer 134 may include, but not be limited to, silicon oxide (SiOₓ), silicon carbon oxide (SiCₓO_{y}), silicon oxynitride (SiOₓN_{y}), or a combination thereof.

A first contact 150 may be disposed on the source/drain region SD. For example, the first contact 150 may include a contact plug 152 and a conductive barrier layer 154 disposed inside a first contact hole 150H penetrating the inter-gate insulating layer 132 and/or the upper insulating layer 134. The contact plug 152 may include, but not be limited to, at least one of tungsten (W), cobalt (Co), molybdenum (Mo), nickel (Ni), ruthenium (Ru), copper (Cu), aluminum (Al), a silicide thereof, or an alloy thereof. The conductive barrier layer 154 may include, but not be limited to, at least one of ruthenium (Ru), titanium (Ti), titanium nitride (TiN), tantalum (Ta), tantalum nitride (TaN), tungsten (W), titanium silicon nitride (TiSiN), titanium silicide (TiSi), tungsten silicide (WSi), or a combination thereof. In some embodiments, a metal silicide layer (not shown) may be further disposed between the first contact 150 and the source/drain region SD.

The first contact 150 may be disposed to cover at least a part of an inclined sidewall SD_S of the source/drain region SD. The bottom surface of the first contact 150 may be disposed at a lower level than the uppermost surface SD_T of the source/drain region SD. Accordingly, a relatively large contact region may be secured between the first contact 150 and the source/drain region SD.

The second contact 160 may be disposed on the gate structure GS. The second contact 160 may include a contact plug 162 and a conductive barrier layer 164 surrounding the sidewall and bottom surface of the contact plug 162. The second contact 160 may be disposed inside a second contact hole 160H penetrating the upper insulating layer 134 and the gate capping layer 128 and exposing the upper surface of the gate electrode 122.

A wiring structure WS may be disposed on the upper insulating layer 134. The wiring structure WS may include wiring layers ML1 and ML2 and first and second vias VA1 and VA2. An interlayer insulating layer 172 may be disposed on the upper insulating layer 134 to cover the wiring structure WS. For example, the interlayer insulating layer 172 may include a plurality of material layers. Each material layer may cover the upper and bottom surfaces of each of the first and second wiring layers ML1 and ML2. Alternatively or additionally, each material layer may be disposed to surround sidewalls of the first and second vias VA1 and VA2. In some embodiments, the interlayer insulating layer 172 may include, but not be limited, an oxide layer, a nitride layer, an ultra low-k layer having an ultra low dielectric constant k of approximately 2.2 to approximately 2.4, or a combination thereof.

In some embodiments, as shown in FIGS. 3 to 5, the first via VA1 may be disposed on the upper surface of the first contact 150 or the second contact 160, the first wiring layer ML1 may be disposed on the upper surface of the first via VA1, the second via VA2 may be disposed on the upper surface of the first wiring layer ML1, and the second wiring layer ML2 may be disposed on the upper surface of the second via VA2. For example, the first wiring layer ML1 may extend in the first horizontal direction X, and the second wiring layer ML2 may extend in the second horizontal direction Y. However, the present disclosure is not limited in this regard. For example, each of the first and second wiring layers ML1 and ML2 may include three or more wiring layers, and the extension direction of each of the first and second wiring layers ML1 and ML2 is not limited to those shown in FIGS. 3 to 5.

Typically, in related integrated circuit devices, gate electrode having a certain length may be formed by performing at least one of the following operations: a part of a sacrificial gate line may be removed, a gate cut insulating pattern may be first formed in the space from which the part has been removed, the remaining part of the sacrificial gate line may be removed, and a gate electrode including a metal may be filled in the space from which the remaining part has been removed. However, as a degree of integration of a related integrated circuit device increases, a distance between the gate cut insulating pattern and each of a plurality of semiconductor patterns may also decrease. Accordingly, after the gate cut insulating pattern is formed, a difficulty in a process of removing the remaining part of the sacrificial gate line may increase, which may result in a product defect.

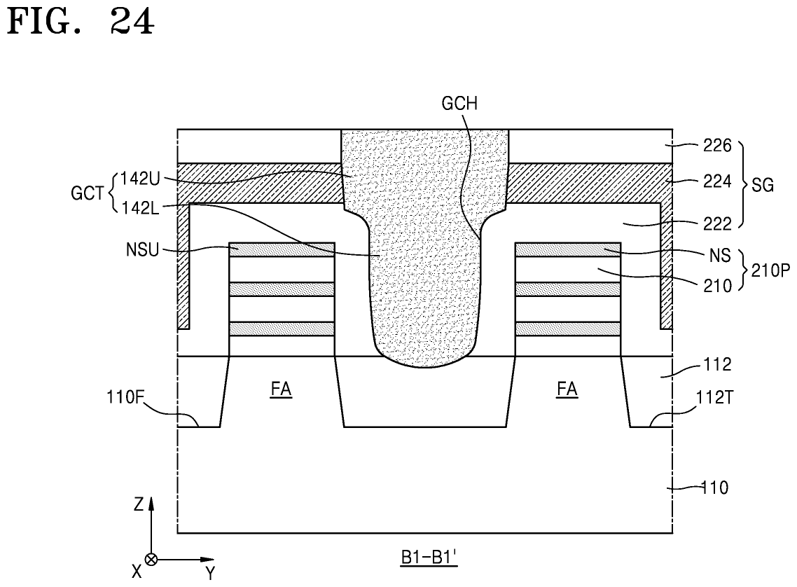

However, according to the integrated circuit device 100 a thick sacrificial insulating layer pattern 222 (e.g., as shown in FIG. 24) may be formed, and a sacrificial gate line 224 (e.g., as shown in FIG. 24) may be formed thereon. Accordingly, the gate cut insulating pattern GCT may be formed using the thick sacrificial insulating layer pattern 222 as a self-aligning mask. As a result, instead of removing the sacrificial gate line 224 in a relatively narrow space between the gate cut insulating pattern GCT and the plurality of semiconductor patterns NS, the thick sacrificial insulating layer pattern 222 (e.g., as shown in FIG. 24) may be removed, and the process of removing the thick sacrificial insulating layer pattern 222 may be a relatively low difficulty process, when compared to a similar operation on a related integrated circuit device. Consequently, the product defect caused by the removing of the sacrificial gate line 224 may be prevented.

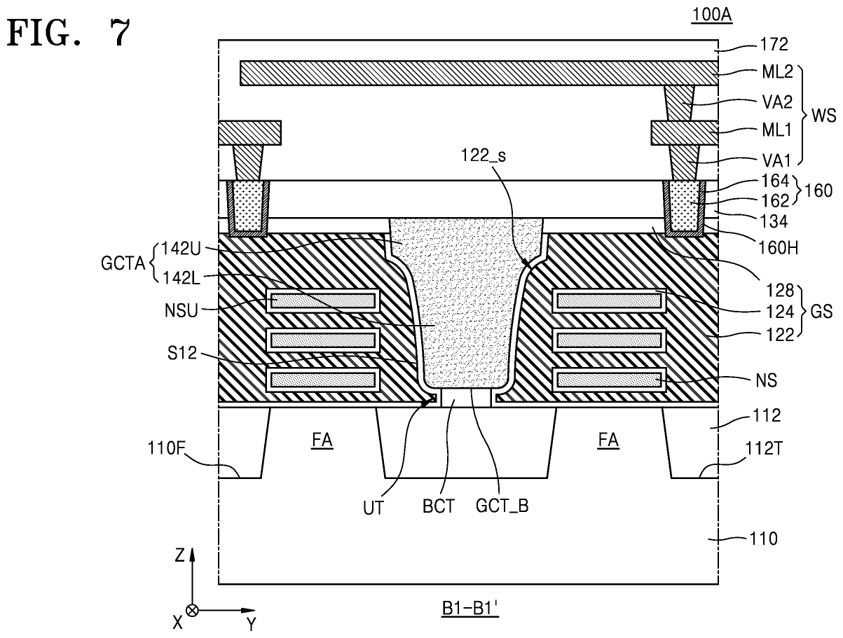

FIG. 7 is a cross-sectional view illustrating an integrated circuit device 100A, according to some embodiments. The integrated circuit device 100A of FIG. 7 may include or may be similar in many respects to the integrated circuit device 100 of FIGS. 1 to 6, and may include additional features not mentioned above. Some of the elements of the integrated circuit device 100A described above with reference of FIGS. 1 to 6 have been omitted for the sake of simplicity.

Referring to FIG. 7, a gate cut insulating pattern GCTA may include the upper portion 142U and the lower portion 142L. A width of the upper portion 142U in the second horizontal direction Y may be greater than a width of the lower portion 142L in the second horizontal direction Y. A bottom surface of the gate cut insulating pattern GCTA may be disposed at a higher level than a bottom surface of the gate electrode 122.

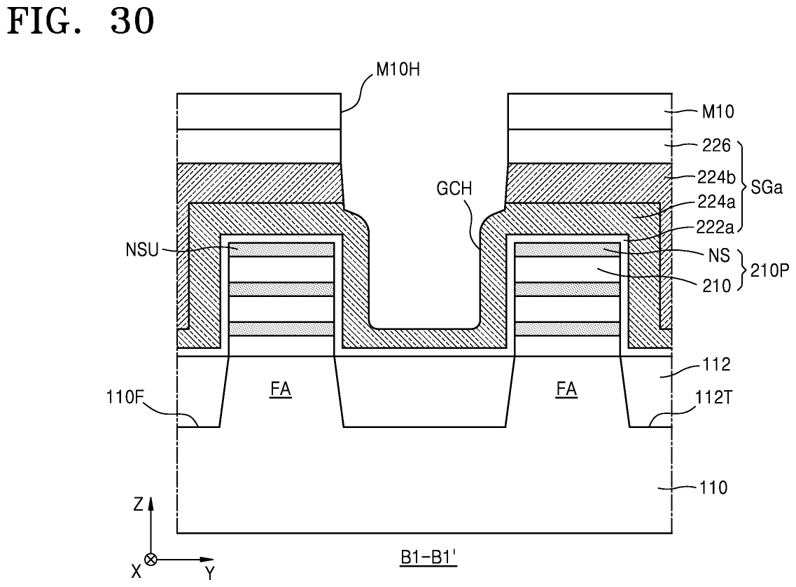

A bottom insulating pattern BCT may be disposed between the gate cut insulating pattern GCTA and the device isolation layer 112. The bottom insulating pattern BCT may correspond to a part where the thick sacrificial insulating layer pattern 222 (e.g., as shown in FIG. 30) disposed below the gate cut insulating pattern GCTA remains without being removed. In some embodiments, the thickness of the bottom insulating pattern BCT in the vertical direction Z may be in the range of approximately 5 nm to approximately 15 nm. However, the present disclosure is not limited in this regard.

In some embodiments, a width of the bottom insulating pattern BCT in the second horizontal direction Y may be less than a width of the lower portion 142L of the gate cut insulating pattern GCTA in the second horizontal direction Y. Accordingly, an undercut region UT may be formed below the gate cut insulating pattern GCTA. The gate insulating layer 124 may be disposed between the fin-type active region FA and the bottom surface of the gate electrode 122, and may be conformally disposed on the sidewall of the bottom insulating pattern BCT and the sidewall of the gate cut insulating pattern GCTA inside the undercut region UT.

The bottom insulating pattern BCT may be disposed between the gate cut insulating pattern GCTA and the device isolation layer 112. Accordingly, the bottom surface of the gate cut insulating pattern GCTA may not directly contact the upper surface of the device isolation layer 112.

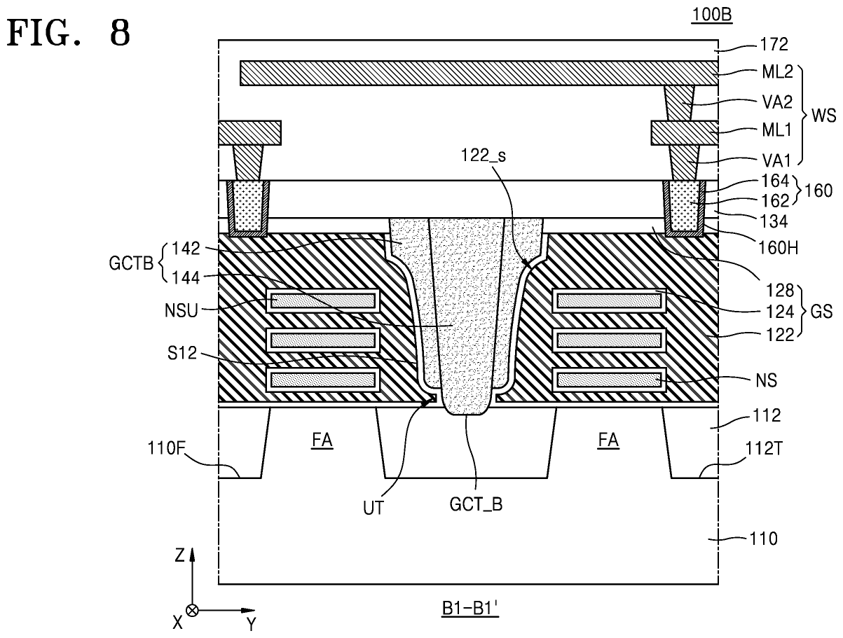

FIG. 8 is a cross-sectional view illustrating an integrated circuit device 100B, according to some embodiments. The integrated circuit device 100B of FIG. 8 may include or may be similar in many respects to at least one of the integrated circuit devices of FIGS. 1 to 7, and may include additional features not mentioned above. Some of the elements of the integrated circuit device 100B described above with reference of FIGS. 1 to 7 have been omitted for the sake of simplicity.

Referring to FIG. 8, a gate cut insulating pattern GCTB may include two first insulating layers 142 and a second insulating layer 144. The two first insulating layers 142 may include a curved sidewall facing the shoulder portion 122_s of the gate electrode 122. The second insulating layer 144 may be disposed between the two first insulating layers 142 such that at least two sidewalls of the second insulating layer 144 are surrounded by the first insulating layers 142.

The two first insulating layers 142 may have an upper surface disposed at the same level as the upper surface of the gate structure GS (e.g., the upper surface of the gate capping layer 128). Alternatively or additionally, the bottom surface of the two first insulating layers 142 may be disposed at a higher level than the upper surface of the device isolation layer 112. The second insulating layer 144 may have an upper surface disposed at the same level as the upper surface of the two first insulating layers 142 or the upper surface of the gate structure GS (e.g., the upper surface of the gate capping layer 128). Alternatively or additionally, the bottom surface of the second insulating layer 144 may be disposed at a lower level than the bottom surface of the gate electrode 122 or the upper surface of the device isolation layer 112.

The undercut region UT may be defined by the bottom surface of the first insulating layer 142, the sidewall of the bottom portion of the second insulating layer 144, and the upper surface of the device isolation layer 112. Alternatively or additionally, the gate insulating layer 124 may be conformally disposed on the bottom surface of the first insulating layer 142, the sidewall of the bottom portion of the second insulating layer 144, and the upper surface of the device isolation layer 112 inside the undercut region UT. In some embodiments, the gate electrode 122 may not directly contact the gate cut insulating pattern GCTB due to the gate insulating layer 124 disposed therebetween. For example, the gate electrode 122 may not directly contact the two first insulating layers 142 and the second insulating layer 144.

In some embodiments, according to a manufacturing method of the integrated circuit device 100B, the two first insulating layers 142 may be formed using the thick sacrificial insulating layer pattern 222 (e.g., as shown in FIG. 24) as a self-aligned mask. Alternatively or additionally, the gate cut insulating pattern GCTB may be formed by removing a part of the two first insulating layers 142 and a part of the thick sacrificial insulating layer pattern 222 using an additional mask pattern, and forming the second insulating layer 144 in the space from which the part has been removed.

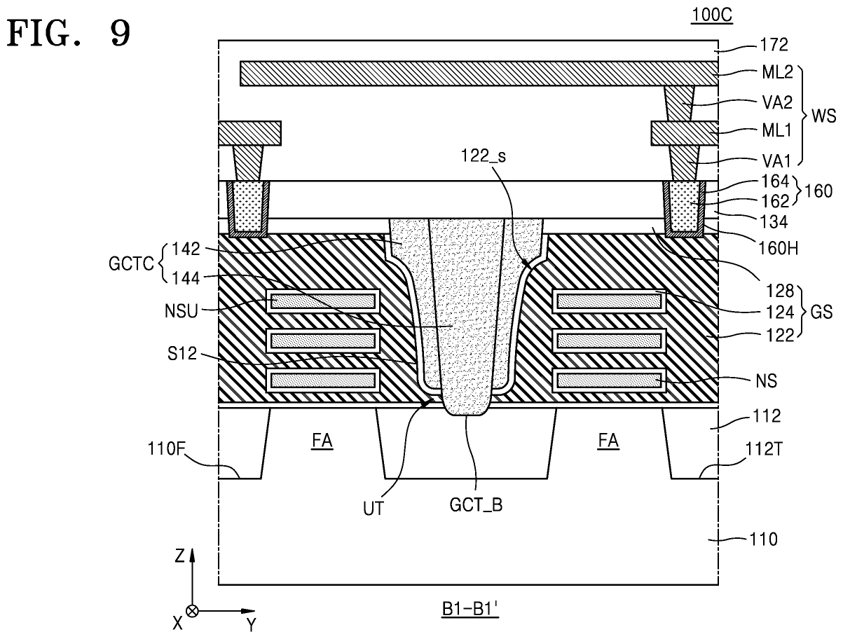

FIG. 9 is a cross-sectional view illustrating an integrated circuit device 100C, according to some embodiments. The integrated circuit device 100C of FIG. 9 may include or may be similar in many respects to at least one of the integrated circuit devices of FIGS. 1 to 8, and may include additional features not mentioned above. Some of the elements of the integrated circuit device 100C described above with reference of FIGS. 1 to 8 have been omitted for the sake of simplicity.

Referring to FIG. 9, a gate cut insulating pattern GCTC may include two first insulating layers 142 and the second insulating layer 144. The undercut region UT may be defined by the bottom surface of the first insulating layer 142, the sidewall of the bottom portion of the second insulating layer 144, and the upper surface of the device isolation layer 112. Alternatively or additionally, the gate insulating layer 124 may be disposed on the bottom surface of the first insulating layer 142 and the upper surface of the device isolation layer 112 inside the undercut region UT. In some embodiments, the gate insulating layer 124 may not be disposed on a part of the sidewall of the second insulating layer 144 in the undercut region UT, and a part of the sidewall of the second insulating layer 144 that is not covered by the gate insulating layer 124 may contact the gate electrode 122.

In some embodiments, according to a manufacturing method of the integrated circuit device 100C, the two first insulating layers 142 may be formed using the thick sacrificial insulating layer pattern 222 (e.g., as shown in FIG. 24) as a self-aligned mask, the sacrificial gate line 224 and the sacrificial insulating layer pattern 222 may be removed, and the gate electrode 122 may be formed in the space from which the sacrificial gate line 224 and the sacrificial insulating layer pattern 222 have been removed. Alternatively or additionally, the gate cut insulating pattern GCTC may be formed by removing a part of the first insulating layer 142, a part of the gate insulating layer 124, and a part of the gate electrode 122 using an additional mask pattern, and the second insulating layer 144 may be formed in the space from which the parts have been removed.

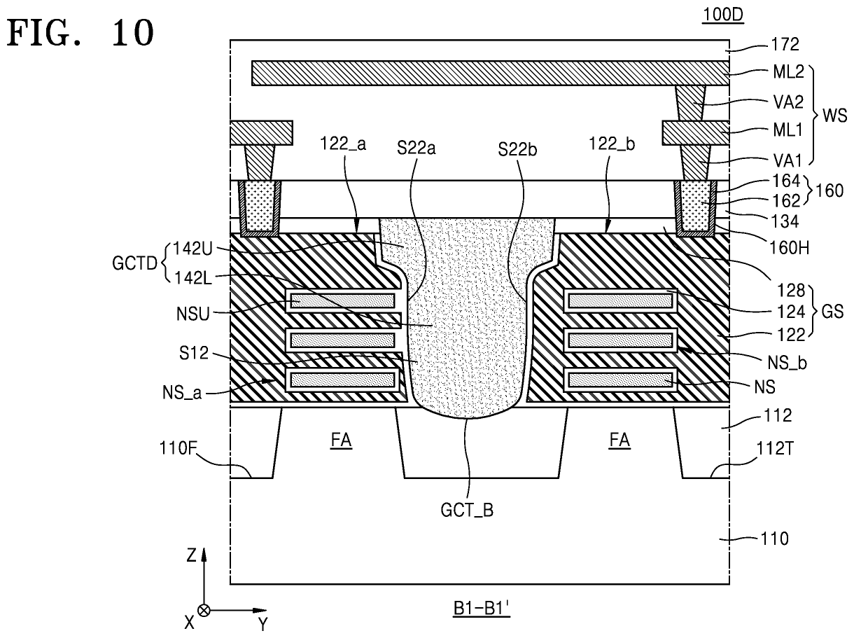

FIG. 10 is a cross-sectional view illustrating an integrated circuit device 100D, according to some embodiments. The integrated circuit device 100D of FIG. 10 may include or may be similar in many respects to at least one of the integrated circuit devices of FIGS. 1 to 9, and may include additional features not mentioned above. Some of the elements of the integrated circuit device 100D described above with reference of FIGS. 1 to 9 have been omitted for the sake of simplicity.

Referring to FIG. 10, a gate cut insulating pattern GCTD may include a first sidewall S22a and a second sidewall S22b spaced apart from each other in the second horizontal direction Y. A distance between the gate cut insulating pattern GCTD and each of a plurality of first semiconductor patterns NS_a surrounded by a first gate electrode 122_a facing the first sidewall S22a of the gate cut insulating pattern GCTD may be different from a distance between the gate cut insulating pattern GCTD and each of a plurality of second semiconductor patterns NS_b surrounded by a second gate electrode 122_b facing the second sidewall S22b of the gate cut insulating pattern GCTD. For example, the distance between each of the plurality of first semiconductor patterns NS_a and the first sidewall S22a of the gate cut insulating pattern GCTD may be relatively small, when compared to other integrated circuit devices (e.g., integrated circuit device 100, integrated circuit device 100A, integrated circuit device 100B, integrated circuit device 100C, related integrated circuit devices). Accordingly, the distance between each of the plurality of second semiconductor patterns NS_b and the second sidewall S22b of the cut insulating pattern GCTD may be relatively large, when compared to other integrated circuit devices (e.g., integrated circuit device 100, integrated circuit device 100A, integrated circuit device 100B, integrated circuit device 100C, related integrated circuit devices).

In some embodiments, a part of the first gate electrode 122_a may not be disposed between at least one of the plurality of first semiconductor patterns NS_a and the gate cut insulating pattern GCTD. Alternatively or additionally, the gate insulating layer 124 may be disposed between at least one of the plurality of first semiconductor patterns NS_a and the gate cut insulating pattern GCTD.

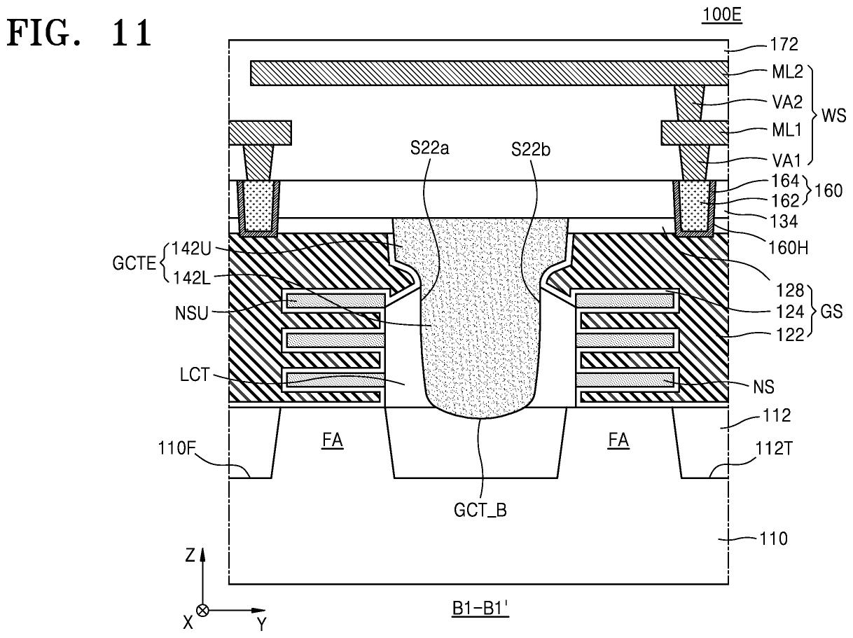

FIG. 11 is a cross-sectional view illustrating an integrated circuit device 100E, according to some embodiments. The integrated circuit device 100E of FIG. 11 may include or may be similar in many respects to at least one of the integrated circuit devices of FIGS. 1 to 10, and may include additional features not mentioned above. Some of the elements of the integrated circuit device 100E described above with reference of FIGS. 1 to 10 have been omitted for the sake of simplicity.

Referring to FIG. 11, a sidewall insulating pattern LCT may be disposed on the device isolation layer 112 between a gate cut insulating pattern GCTE and the plurality of semiconductor patterns NS. For example, the gate electrode 122 may not be disposed between the gate cut insulating pattern GCTE and the plurality of semiconductor patterns NS. The gate electrode 122 may be disposed on the upper surface and a part of the sidewall of the uppermost semiconductor pattern NSU, and may not be disposed between the semiconductor pattern NS other than the uppermost semiconductor pattern NSU (e.g., the semiconductor pattern NS disposed on a lower level than the uppermost semiconductor pattern NSU) and the gate cut insulating pattern GCTE.

In some embodiments, a width of the sidewall insulating pattern LCT in the second horizontal direction Y may be in the range of approximately 5 nm to approximately 15 nm. However, the present disclosure is not limited in this regard.

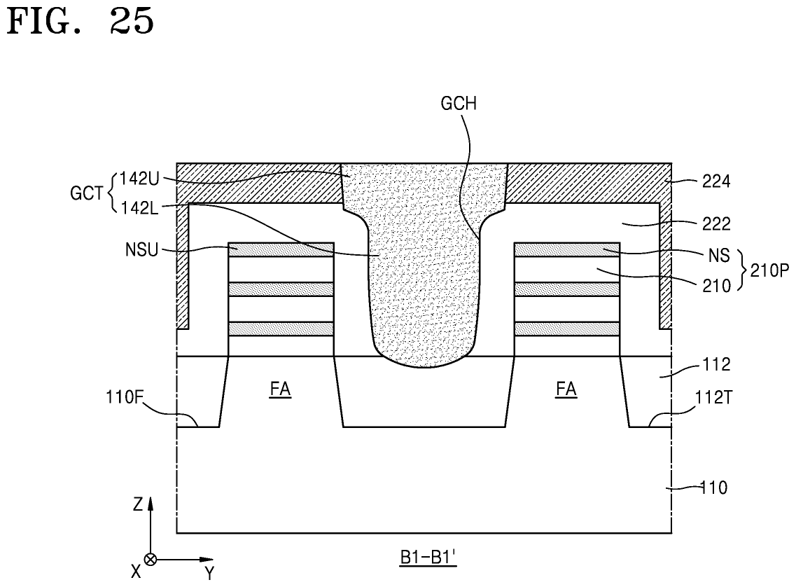

The sidewall insulating pattern LCT may correspond to a part where the thick sacrificial insulating layer pattern 222 (as shown in FIG. 25) disposed between the gate cut insulating pattern GCTE and the plurality of semiconductor patterns NS remains without being removed.

As shown in FIG. 11, the sidewall insulating pattern LCT may be formed on both the first sidewall S22a and the second sidewall S22b of the gate cut insulating pattern GCTE. In some optional or additional embodiments, the sidewall insulating pattern LCT may be formed only on the first sidewall S22a of the gate cut insulating pattern GCTE, and the gate electrode 122 may be disposed on the second sidewall S22b. In other optional or additional embodiments, the sidewall insulating pattern LCT may be formed only on the second sidewall S22b of the gate cut insulating pattern GCTE, and the gate electrode 122 may be disposed on the first sidewall S22a.

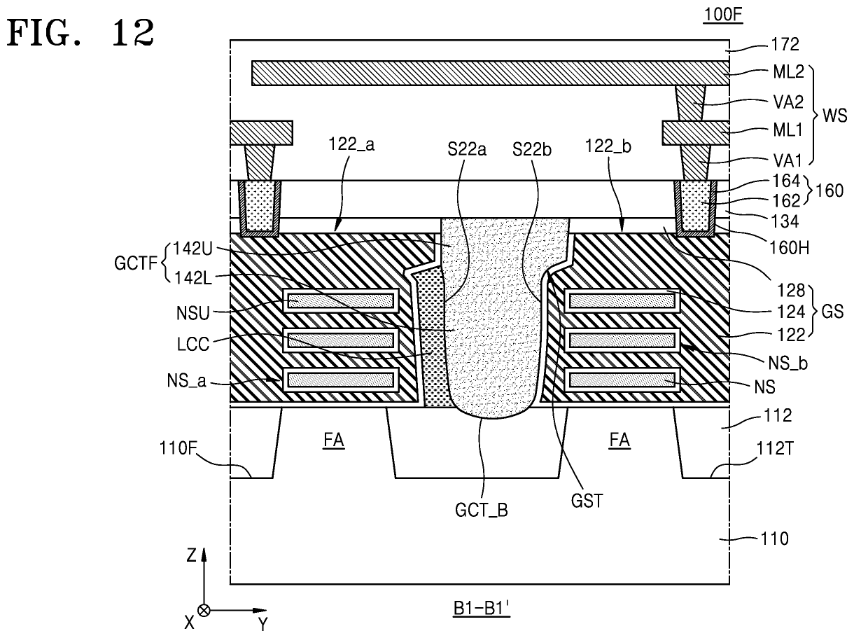

FIG. 12 is a cross-sectional view illustrating an integrated circuit device 100F, according to some embodiments. The integrated circuit device 100F of FIG. 12 may include or may be similar in many respects to at least one of the integrated circuit devices of FIGS. 1 to 11, and may include additional features not mentioned above. Some of the elements of the integrated circuit device 100F described above with reference of FIGS. 1 to 11 have been omitted for the sake of simplicity.

Referring to FIG. 12, the first sidewall S22a and the second sidewall S22b of a gate cut insulating pattern GCTF may have an asymmetric shape with respect to each other. A sidewall conductive pattern LCC may be disposed on the first sidewall S22a of the gate cut insulating pattern GCTF. For example, the first sidewall S22a of the gate cut insulating pattern GCTF may extend in a substantially vertical direction, and the second sidewall S22b of the gate cut insulating pattern GCTF may include the stepped portion GST.

The gate electrode 122 and the sidewall conductive pattern LCC may be disposed between the first sidewall S22a of the gate cut insulating pattern GCTF and the plurality of semiconductor patterns NS. The gate insulating layer 124 may extend from between the fin-type active region FA and the bottom surface of the gate electrode 122 onto the sidewall of the sidewall conductive pattern LCC.

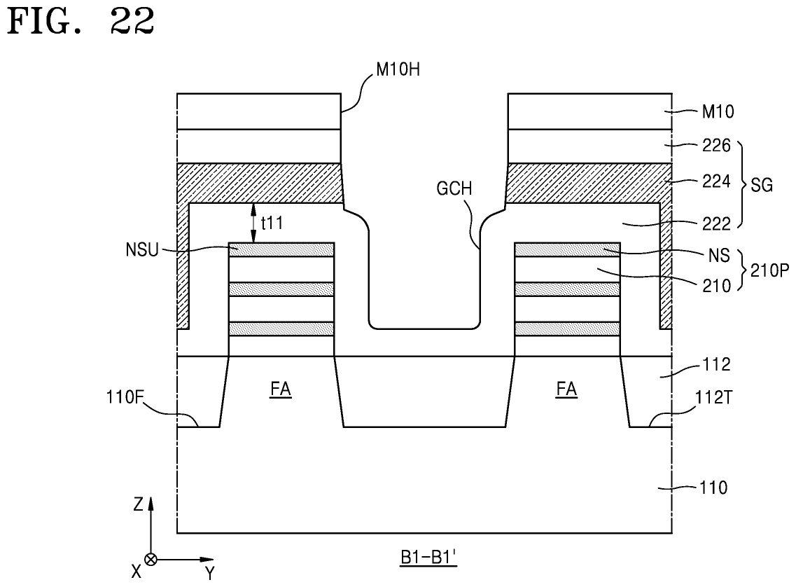

In some embodiments, according to a manufacturing method of the integrated circuit device 100F, a mask pattern M10 (e.g., as shown in FIG. 22) for forming the gate cut insulating pattern GCTF may be misaligned, and self-aligned patterning may not be performed because the mask pattern M10 and the thick sacrificial insulating layer pattern 222 do not overlap each other. In such an example, a part of the sacrificial gate line 224 (e.g., as shown in FIG. 25) disposed in a relatively narrow space between the gate cut insulating pattern GCTF and the plurality of semiconductor patterns NS may remain without being removed during a process of removing the sacrificial gate line 224. In some embodiments, the remaining part of the sacrificial gate line 224 may be referred to as the sidewall conductive pattern LCC.

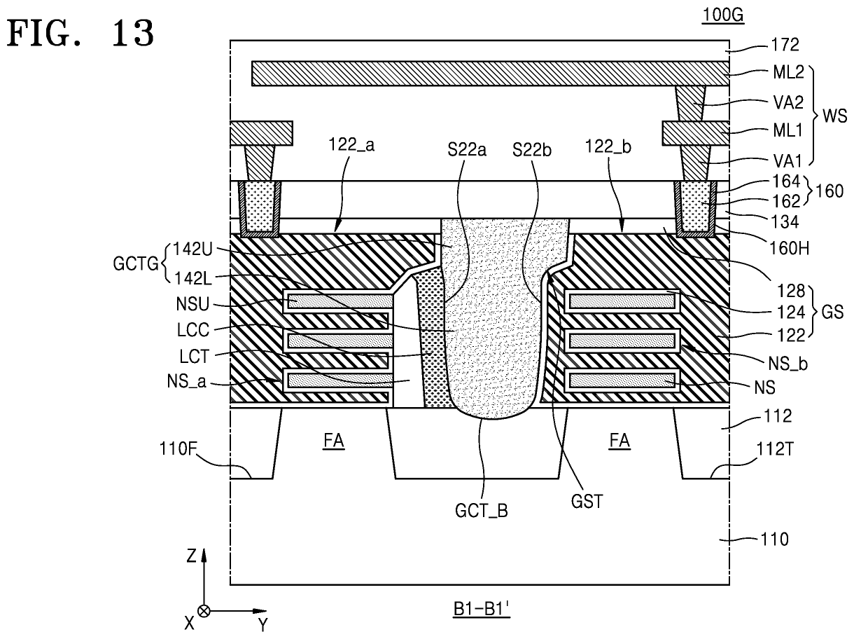

FIG. 13 is a cross-sectional view illustrating an integrated circuit device 100G, according to some embodiments. The integrated circuit device 100G of FIG. 13 may include or may be similar in many respects to at least one of the integrated circuit devices of FIGS. 1 to 12, and may include additional features not mentioned above. Some of the elements of the integrated circuit device 100G described above with reference of FIGS. 1 to 12 have been omitted for the sake of simplicity.

Referring to FIG. 13, the sidewall conductive pattern LCC and a sidewall insulating pattern LCT may be disposed on the first sidewall S22a of a gate cut insulating pattern GCTG. For example, the first sidewall S22a of the gate cut insulating pattern GCTG may extend in a substantially vertical direction, and the sidewall conductive pattern LCC and the sidewall insulating pattern LCT may be disposed between the first sidewall S22a of the gate cut insulating pattern GCTG and the plurality of semiconductor patterns NS. Alternatively or additionally, the gate electrode 122 may not be disposed between the first sidewall S22a of the gate cut insulating pattern GCTG and the plurality of semiconductor patterns NS.

In some embodiments, according to a manufacturing method of the integrated circuit device 100G, the mask pattern M10 (e.g., as shown in FIG. 22) for forming the gate cut insulating pattern GCTG may be misaligned, and self-aligned patterning may not be performed because the mask pattern M10 and the thick sacrificial insulating layer pattern 222 do not overlap. In such an example, a part of the thick sacrificial insulating layer pattern 222 and the sacrificial gate line 224 (e.g., as shown in FIG. 25) disposed in a relatively narrow space between the gate cut insulating pattern GCTG and the plurality of semiconductor patterns NS may remain without being removed.

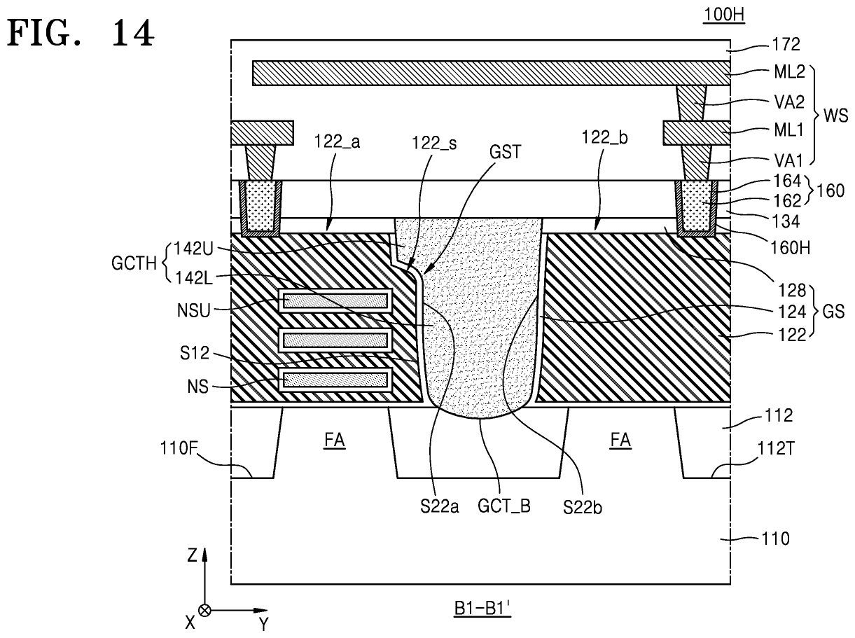

FIG. 14 is a cross-sectional view illustrating an integrated circuit device 100H, according to some embodiments. The integrated circuit device 100H of FIG. 14 may include or may be similar in many respects to at least one of the integrated circuit devices of FIGS. 1 to 13, and may include additional features not mentioned above. Some of the elements of the integrated circuit device 100H described above with reference of FIGS. 1 to 13 have been omitted for the sake of simplicity.

Referring to FIG. 14, the first sidewall S22a and the second sidewall S22b of a gate cut insulating pattern GCTH may have an asymmetric shape with respect to each other. The plurality of semiconductor patterns NS may be disposed to face the first sidewall S22a of the gate cut insulating pattern GCTH. The first sidewall S22a may include the stepped portion GST corresponding to the shoulder portion 122_s of the first gate electrode 122_a, and the second sidewall S22b may extend substantially vertically. For example, the first gate electrode 122_a may be disposed to surround the plurality of semiconductor patterns NS disposed adjacent to the gate cut insulating pattern GCTH. Alternatively or additionally, a part of the second gate electrode 122_b disposed adjacent to the gate cut insulating pattern GCTH may be disposed on the device isolation layer 112. In some embodiments, the fin-type active region FA and the semiconductor pattern NS may not be disposed below a part of the second gate electrode 122_b.

Accordingly, the first sidewall S22a of the gate cut insulating pattern GCTH may be formed using the thick sacrificial insulating layer pattern 222 (e.g., as shown in FIG. 22) on the plurality of semiconductor patterns NS as a self-aligned mask, and the second sidewall S22b of the gate cut insulating pattern GCTH may be formed using the mask pattern M10 (e.g., as shown in FIG. 22) as an etch mask.

The integrated circuit devices 100A, 100B, 100C, 100D, 100E, 100F, and 100G described above with reference to FIGS. 7 to 13 have structures in which the fin-type active region FA and the plurality of semiconductor patterns NS are disposed on both sides of each of the gate cut insulating patterns GCTA, GCTB, GCTC, GCTD, GCTE, GCTF, and GCTG. However, in some embodiments, the fin-type active region FA and the plurality of semiconductor patterns NS may be disposed on only one side of each of the gate cut insulating patterns GCTA, GCTB, GCTC, GCTD, GCTE, GCTF, and GCTG, and the fin-type active region FA and the plurality of semiconductor patterns NS may not be disposed on the other side of each of the gate cut insulating patterns GCTA, GCTB, GCTC, GCTD, GCTE, GCTF, and GCTG. In such embodiments, the gate cut insulating patterns GCTA, GCTB, GCTC, GCTD, GCTE, GCTF, and GCTG may have an asymmetrical shape similar to the shape of the gate cut insulating pattern GCTH.

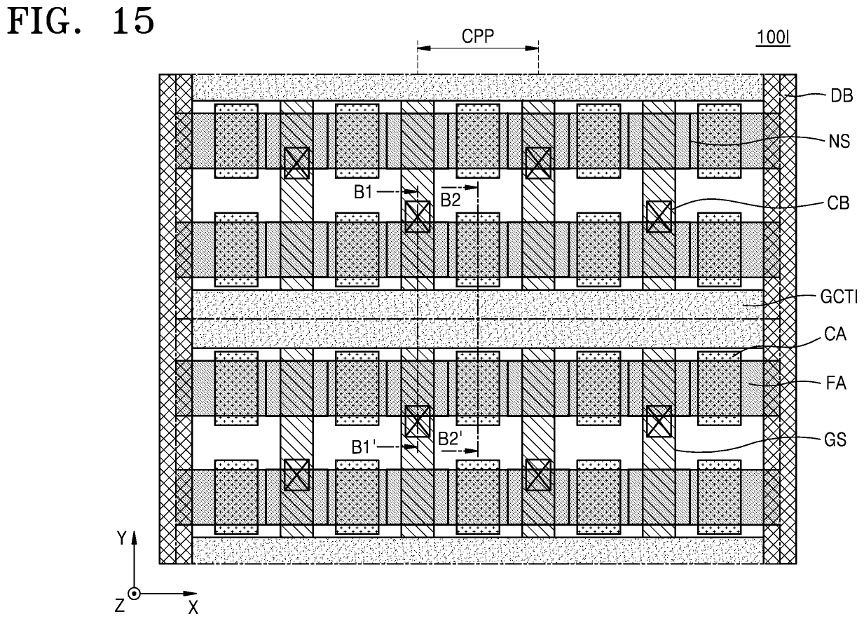

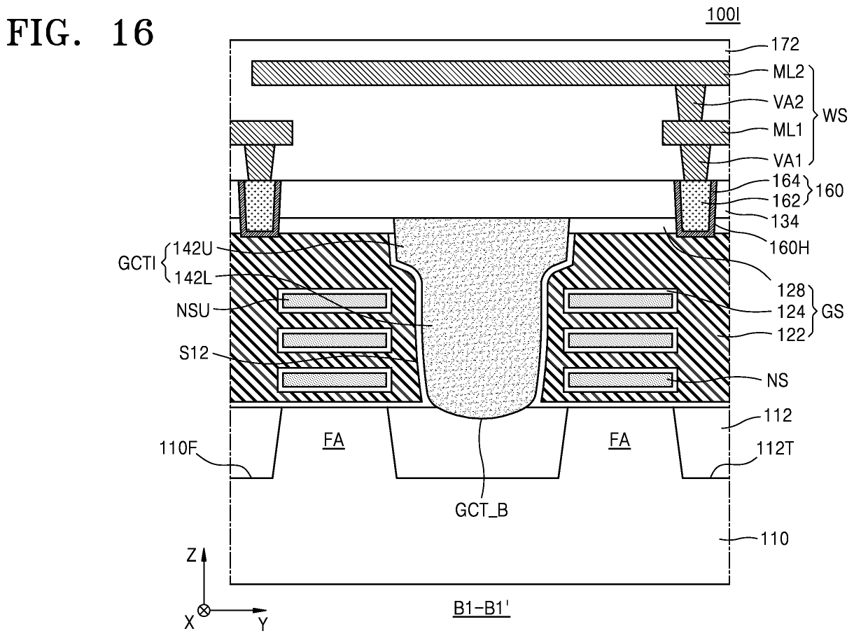

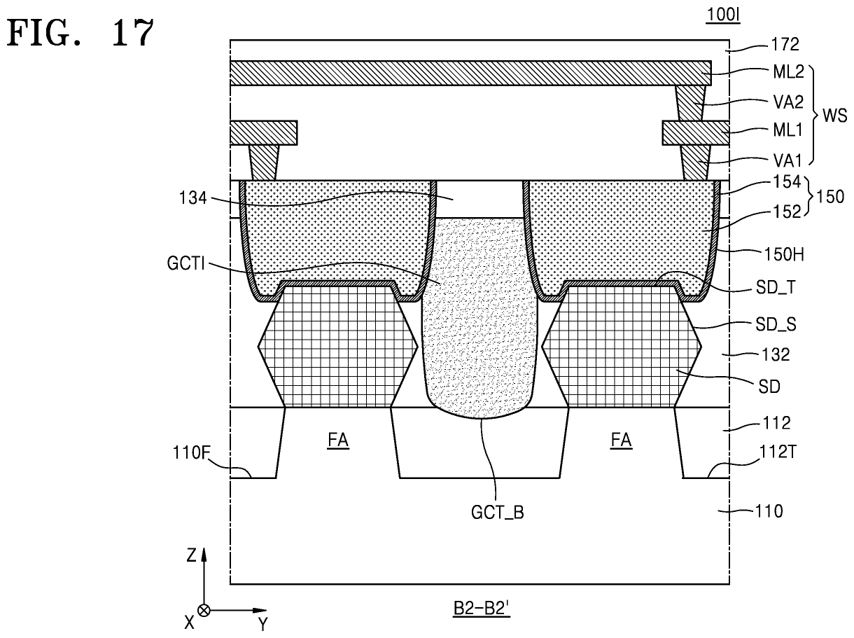

FIG. 15 is a layout diagram illustrating an integrated circuit device 100I, according to some embodiments. FIG. 16 is a cross-sectional view taken along line B1-B1′ in FIG. 15, according to some embodiments. FIG. 17 is a cross-sectional view taken along line B2-B2′ in FIG. 15, according to some embodiments. The integrated circuit device 100I of FIGS. 15 to 17 may include or may be similar in many respects to at least one of the integrated circuit devices of FIGS. 1 to 14, and may include additional features not mentioned above. Some of the elements of the integrated circuit device 100I described above with reference of FIGS. 1 to 14 have been omitted for the sake of simplicity.

Referring to FIGS. 15 to 17, a gate cut insulating pattern GCTI may extend in the first horizontal direction X, and may contact sidewalls of the plurality of gate electrodes 122 disposed in the first horizontal direction X. The gate cut insulating pattern GCTI may be disposed between two adjacent gate electrodes 122 in the second horizontal direction Y and between two adjacent source/drain regions SD in the second horizontal direction Y. In some embodiments, as shown in FIG. 17, a part of the sidewall of the gate cut insulating pattern GCTI may contact the first contact 150 disposed on the source/drain region SD. However, the present disclosure is not limited in this regard.

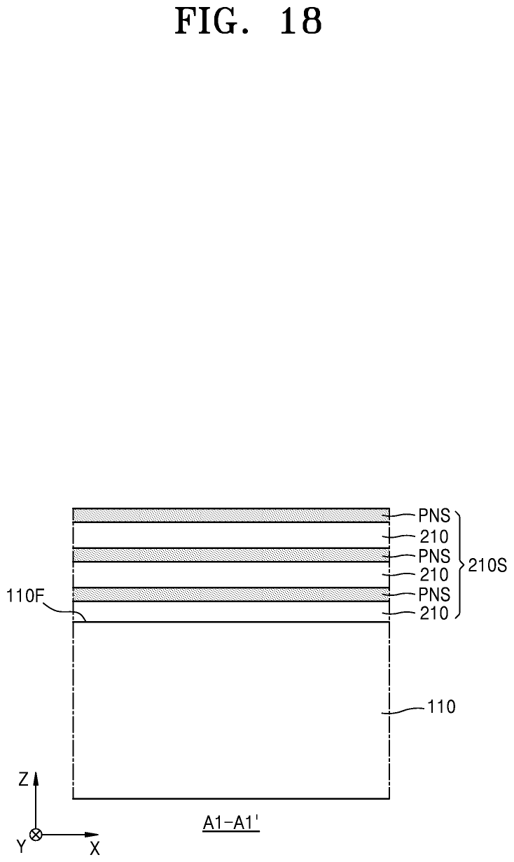

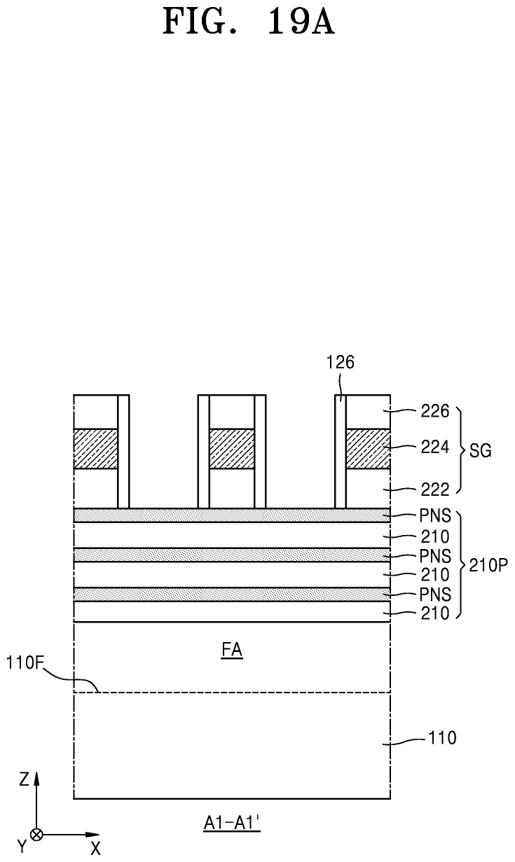

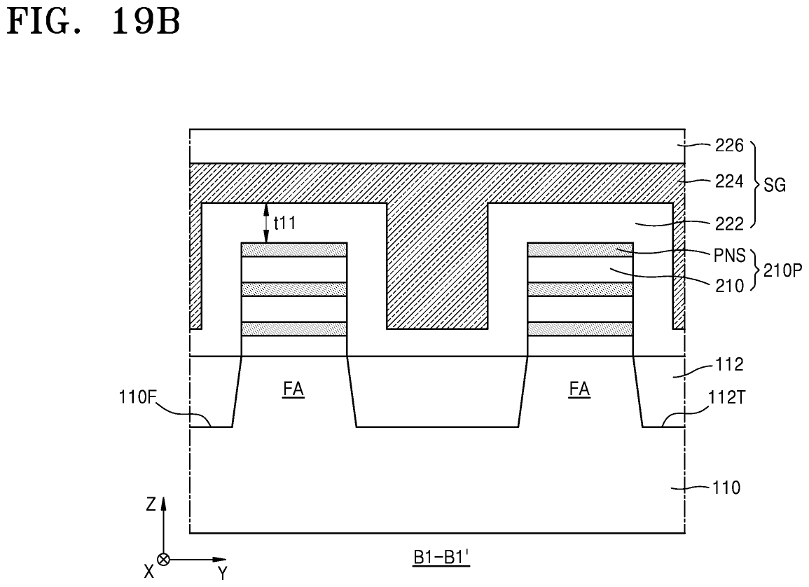

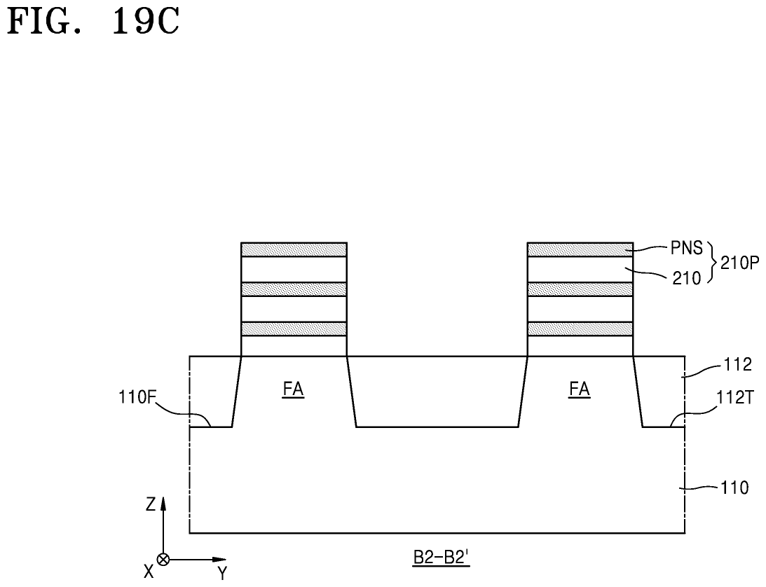

FIGS. 18 to 29C are cross-sectional views illustrating a manufacturing method of the integrated circuit device 100, according to some embodiments. Specifically, FIGS. 18, 19A, 20A, 21A, 26A, 28A, and 29A are cross-sectional views corresponding to the cross-section taken along line A1-A1′ of FIG. 2. FIGS. 19B, 20B, 21B, 22, 23, 24, 25, 26B, 27, 28B, and 29B are cross-sectional views corresponding to the cross-section taken along line B1-B1′ in FIG. 2. FIGS. 19C, 20C, and 29C are cross-sectional views corresponding to the cross-section taken along line B2-B2′ in FIG. 2.

Referring to FIG. 18, a sacrificial layer stack 210S may be formed by alternately and sequentially forming a sacrificial layer 210 and a channel semiconductor layer PNS on the first surface 110F of the substrate 110. The sacrificial layer 210 and the channel semiconductor layer PNS may be formed by an epitaxial growth process, for example.

In some embodiments, the sacrificial layer 210 and the channel semiconductor layer PNS may include materials having an etch selectivity with respect to each other. For example, each of the sacrificial layer 210 and the channel semiconductor layer PNS may include, but not be limited to, a single crystal layer of a group IV semiconductor, a group IV-IV compound semiconductor, or a group III-V compound semiconductor. The sacrificial layer 210 and the channel semiconductor layer PNS may include different materials. For example, the sacrificial layer 210 may include silicon germanium (SiGe), and the channel semiconductor layer PNS may include single crystal silicon.

In some embodiments, the epitaxial growth process may include, but not be limited to, a chemical vapor deposition (CVD) process such as vapor-phase epitaxy (VPE), ultra-high vacuum CVD (UHV-CVD), molecular beam epitaxy, or a combination thereof. In the epitaxial growth process, a liquid or gaseous precursor may be used as a precursor necessary for forming the sacrificial layer 210 and the channel semiconductor layer PNS.

Referring to FIGS. 19A to 19C, the channel semiconductor layer pattern 210P and the device isolation trench 112T may be formed by forming a hard mask pattern (not shown) extending a certain length in a first direction (e.g., X direction) on the channel semiconductor layer PNS, and subsequently etching the sacrificial layer 210, the channel semiconductor layer PNS, and the substrate 110 using the hard mask pattern as an etch mask.

In some embodiments, the device isolation layer 112 filling the device isolation trench 112T may be formed by filling the inside of the device isolation trench 112T with an insulating material, and subsequently planarizing an upper portion of the insulating material. The fin-type active region FA may be defined on the substrate 110 by the device isolation layer 112.

In some embodiments, a sacrificial gate structure SG may be formed on the channel semiconductor layer pattern 210P and the device isolation layer 112. Each of the sacrificial gate structures SG may include the sacrificial insulating layer pattern 222, the sacrificial gate line 224, and a sacrificial gate capping layer 226. The sacrificial insulating layer pattern 222 may extend in the second horizontal direction Y and may be conformally formed on the upper surface and sidewall of the channel semiconductor layer pattern 210P and the upper surface of the device isolation layer 112. In some embodiments, the sacrificial insulating layer pattern 222 may be formed to have a thickness t11 of approximately 5 nm to approximately 15 nm.

In some embodiments, the sacrificial gate line 224 may include polysilicon, and the sacrificial gate capping layer 226 may include silicon nitride (SiNₓ). The sacrificial insulating layer pattern 222 may include a material having an etching selectivity with a material of the sacrificial gate line 224, and may include, for example, at least one layer including thermal oxide, silicon oxide (SiOₓ), or silicon nitride (SiNₓ).

In some embodiments, the gate spacers 126 may be formed on sidewalls of the sacrificial gate structure SG. In some embodiments, the gate spacers 126 may remain on both sidewalls of the sacrificial gate structure SG by forming an insulating layer (not shown) on the sacrificial gate structure SG and the device isolation layer 112, and performing an anisotropic etching process on the insulating layer. In some embodiments, the gate spacer 126 may include, but not be limited to, silicon oxide (SiOₓ), silicon nitride (SiNₓ), silicon oxynitride (SiOₓN_{y}), silicon carbonitride (SiCₓN_{y}), silicon oxycarbonitride (SiOₓC_{y}N_{z}), or a combination thereof.

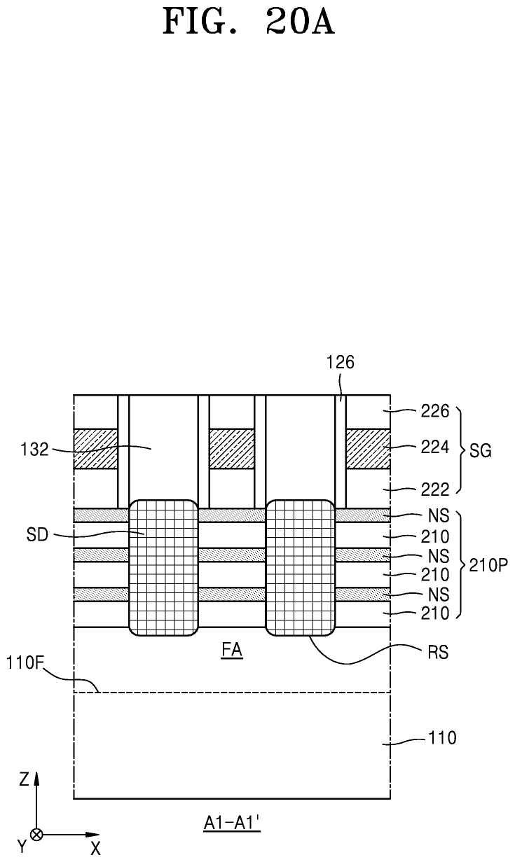

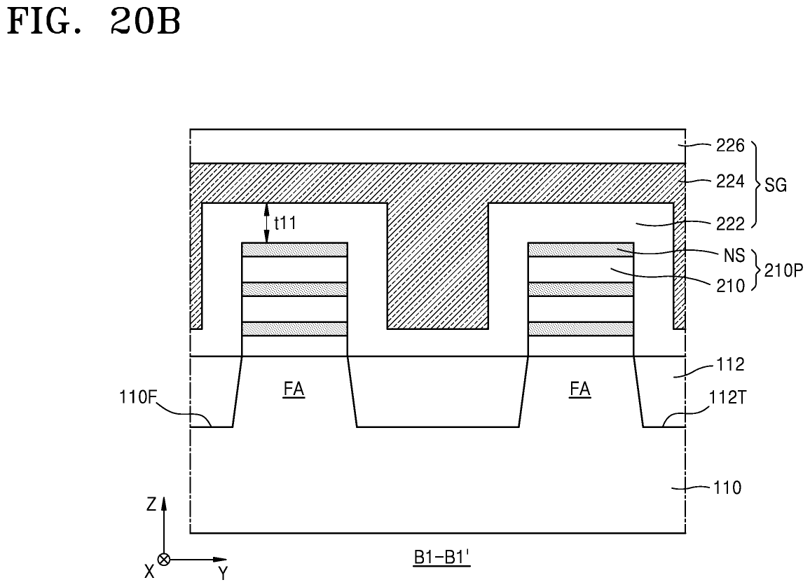

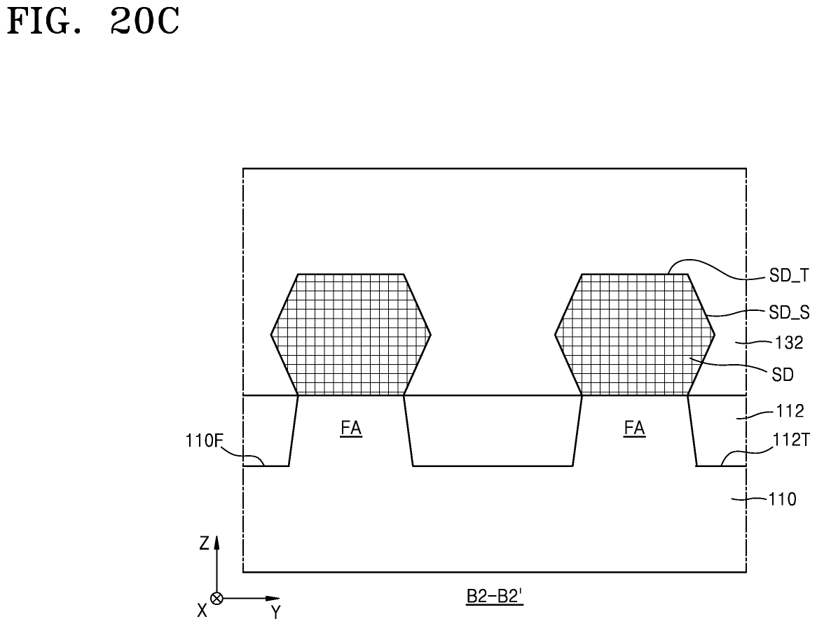

Referring to FIGS. 20A to 20C, the recess RS may be formed on both sides of the sacrificial gate structure SG by etching a part of the substrate 110 and the channel semiconductor layer pattern 210P on both sides of the sacrificial gate structure SG. As the recess RS is formed, the channel semiconductor layer PNS may be separated into the plurality of semiconductor patterns NS. For example, the recess RS may be formed so that a structure in which the plurality of sacrificial layers 210 and the plurality of semiconductor patterns NS are alternately disposed on the fin-type active region FA.

In some embodiments, the source/drain region SD may be formed in the recess RS. For example, the source/drain region SD may be formed by epitaxially growing a semiconductor material from the plurality of semiconductor patterns NS exposed on the inner wall of the recess RS, the sacrificial layer 210, and the surface of the substrate 110. The source/drain region SD may include, but not be limited to, at least one of an epitaxially grown silicon (Si) layer, an epitaxially grown silicon carbide (SiC) layer, an epitaxially grown silicon germanium (SiGe) layer, or an epitaxially grown silicon phosphorus (SiP) layer. In some embodiments, the source/drain region SD may have the uppermost surface SD_T disposed at a higher level than the uppermost semiconductor pattern NS and a plurality of inclined sidewalls SD_S.

In some embodiments, the inter-gate insulating layer 132 may be formed on the sidewall of the gate spacer 126 and the source/drain region SD. In optional or additional embodiments, the inter-gate insulating layer 132 may include, but not be limited to, silicon oxide (SiOₓ), silicon carbon oxide (SiCₓO_{y}), or silicon oxynitride (SiOₓN_{y}). The upper surface of the inter-gate insulating layer 132 may be disposed on the same plane as the upper surface of the sacrificial gate structure SG.

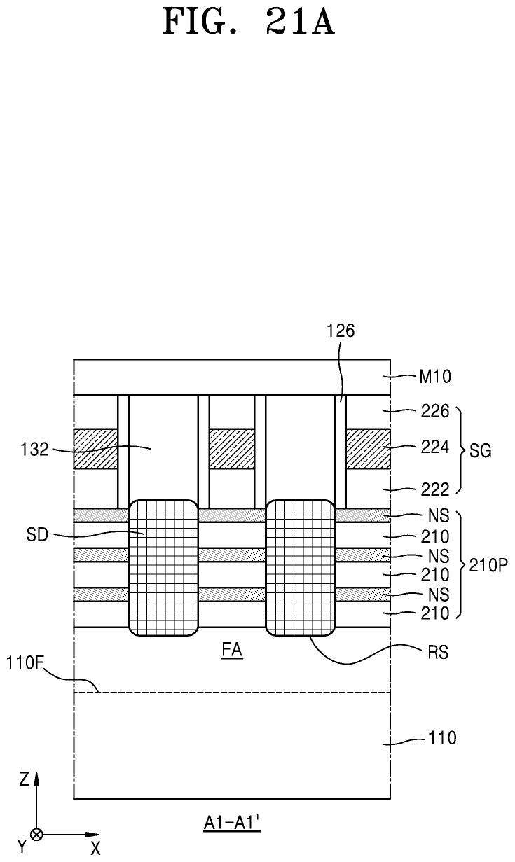

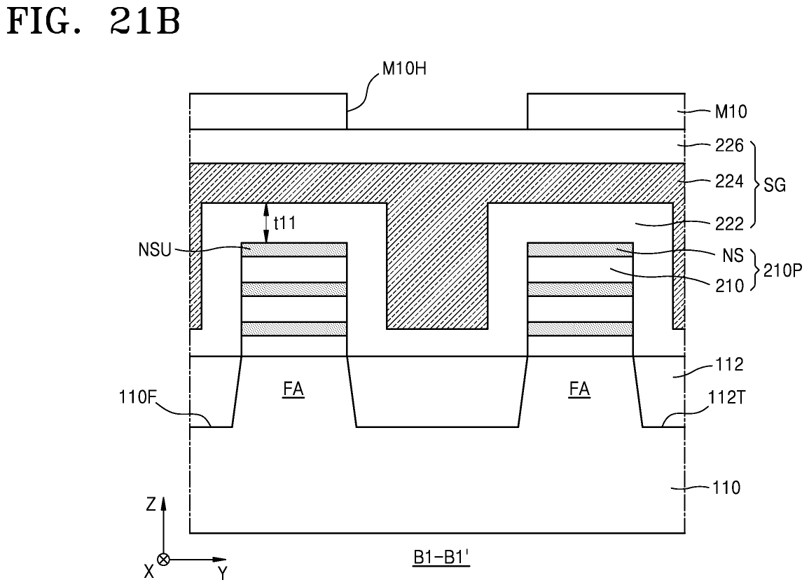

Referring to FIGS. 21A and 21B, the mask pattern M10 may be formed on the inter-gate insulating layer 132 and the sacrificial gate structure SG. The mask pattern M10 may include a plurality of first openings M10H. In some embodiments, the plurality of first openings M10H may extend in the first horizontal direction X. In optional or additional embodiments, the plurality of first openings M10H may be spaced apart from each other in the first horizontal direction X and the second horizontal direction Y. For example, the plurality of first openings M10H may be disposed at positions vertically overlapping the sacrificial gate structure SG.

Referring to FIG. 22, the gate cut opening GCH may be formed by removing a part of the sacrificial gate structure SG using the mask pattern M10 as an etch mask.

In some embodiments, a process of forming the gate cut opening GCH by removing the part of the sacrificial gate structure SG may be a wet etching process or a dry etching process. In optional or additional embodiments, a part of the sacrificial gate capping layer 226 and a part of the sacrificial gate line 224 disposed at positions vertically overlapping the plurality of first openings M10H may be removed.

In some embodiments, the process of forming the gate cut opening GCH by removing the part of the sacrificial gate structure SG may include an etching process using etching conditions of a low etch rate with respect to the sacrificial insulating layer pattern 222 and a high etching rate with respect to the sacrificial gate capping layer 226 and the sacrificial gate line 224. In optional or additional embodiments, an upper surface of a part of the sacrificial insulating layer pattern 222 disposed on the upper surface of the channel semiconductor layer pattern 210P may be exposed in the etching process, and the part of the sacrificial insulating layer pattern 222 may be etched at a relatively low rate in the etching process. Accordingly, the sacrificial gate capping layer 226 and the sacrificial gate line 224 may be etched and/or removed continuously until the upper surface of the sacrificial insulating layer pattern 222 disposed on the upper surface of the device isolation layer 112 is exposed. In this regard, a part of the sacrificial insulating layer pattern 222 disposed on the upper surface of the channel semiconductor layer pattern 210P may be etched relatively small to serve as a self-aligned mask.

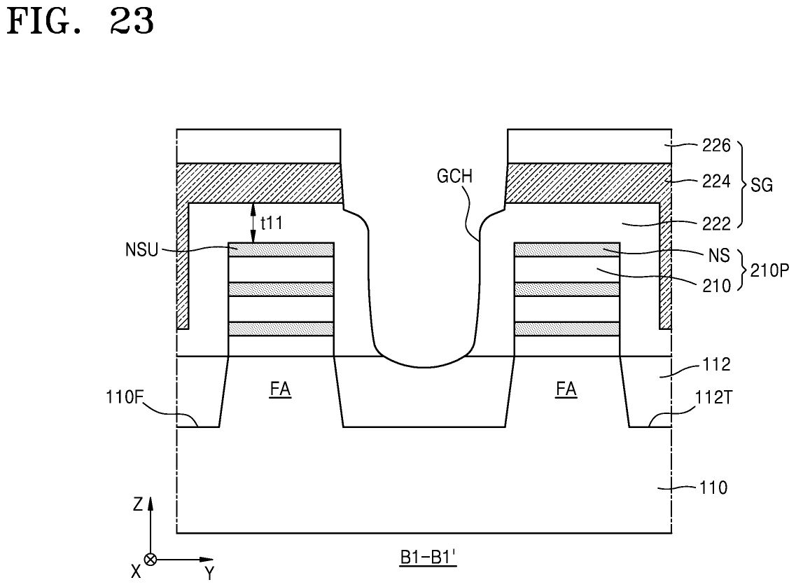

Referring to FIG. 23, a part of the sacrificial insulating layer pattern 222 disposed on the bottom portion of the gate cut opening GCH may be further removed. In a removal process, the upper surface of the device isolation layer 112 may be exposed, and a part of the upper portion of the device isolation layer 112 may be removed together.

In some embodiments, a part of the sacrificial insulation layer pattern 222 surrounding one channel semiconductor layer pattern 210P and a part of the sacrificial insulation layer pattern 222 surrounding another channel semiconductor layer pattern 210P adjacent thereto may be spaced apart from each other by removing a part of the sacrificial insulation layer pattern 222.

Referring to FIG. 24, the gate cut insulating pattern GCT may be formed on the sacrificial gate structure SG and the inter-gate insulating layer 132 to fill the inside of the gate cut opening GCH. In some embodiments, the gate cut insulating pattern GCT may include silicon nitride (SiNₓ).

In some embodiments, the gate cut insulating pattern GCT may include the upper portion 142U and the lower portion 142L. The upper portion 142U may refer to a part of the gate cut insulating pattern GCT disposed at a higher level than the upper surface of the uppermost semiconductor pattern NSU. The lower portion 142L of the gate cut insulating pattern GCT may contact the sidewall of the sacrificial insulating layer pattern 222. The sacrificial gate line 224 may not be disposed between the lower portion 142L of the gate cut insulating pattern GCT and the sidewall of the sacrificial insulating layer pattern 222. For example, the gate cut opening GCH may be formed between parts of the sacrificial insulating layer pattern 222 surrounding two adjacent channel semiconductor layer patterns 210P in a self-aligned manner, and the gate cut insulating pattern GCT may be disposed between parts of the sacrificial insulating layer pattern 222 surrounding two adjacent channel semiconductor layer patterns 210P inside the gate cut opening GCH.

Referring to FIG. 25, the sacrificial gate capping layer 226 may be removed by planarizing upper sides of the sacrificial gate structure SG and the gate cut insulating pattern GCT. The upper surface of the sacrificial gate line 224 may be exposed by a planarization process, and the upper surface of the gate cut insulating pattern GCT may be disposed at the same level as the upper surface of the sacrificial gate line 224.

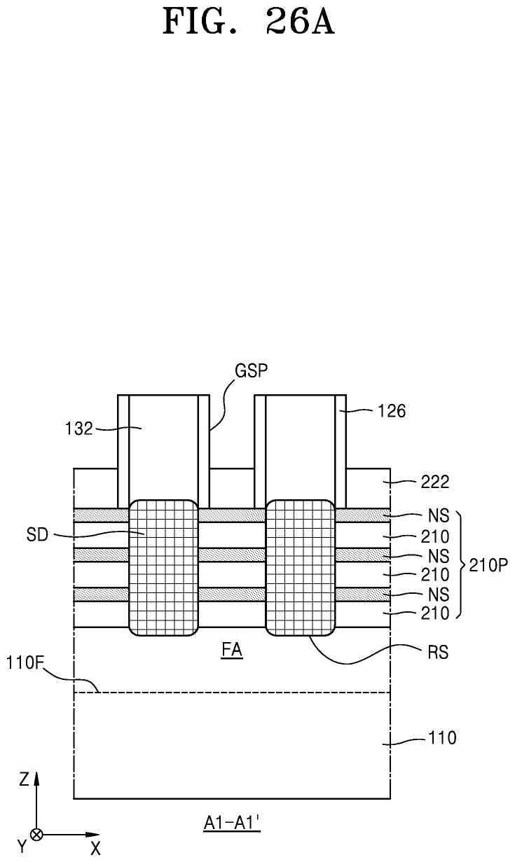

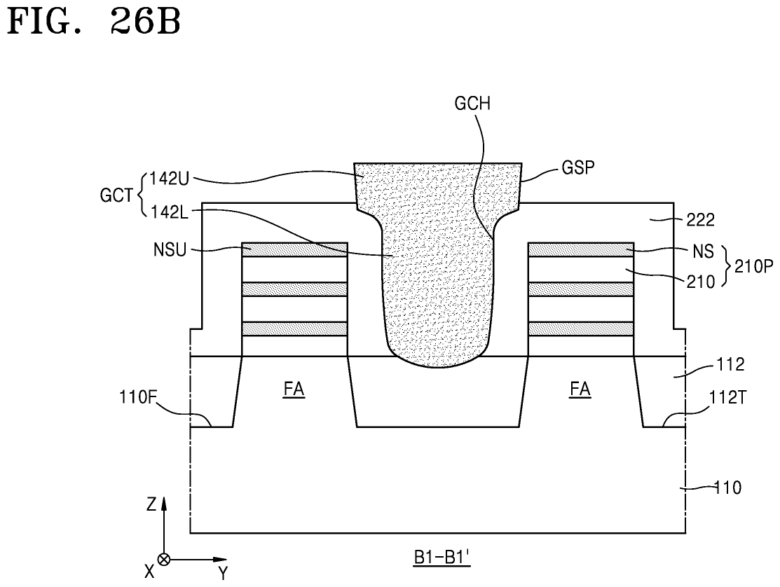

Referring to FIGS. 26A and 26B, a gate space GSP may be formed by removing the sacrificial gate line 224. For example, the gate space GSP may be defined between two adjacent gate spacers 126, and the sacrificial insulating layer pattern 222 may be disposed at the bottom portion of the gate space GSP.

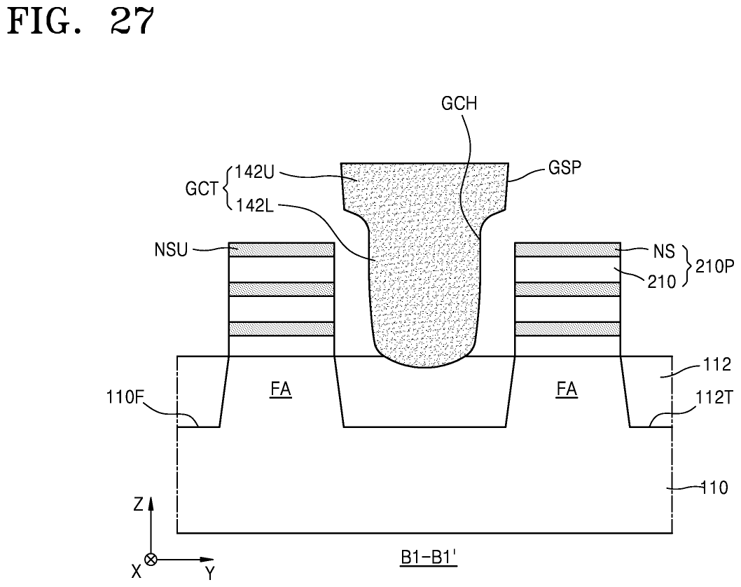

Referring to FIG. 27, the upper surface and the sidewall of the channel semiconductor layer pattern 210P and the upper surface of the device isolation layer 112 may be exposed by removing the sacrificial insulating layer pattern 222 disposed at the bottom portion of the gate space GSP.

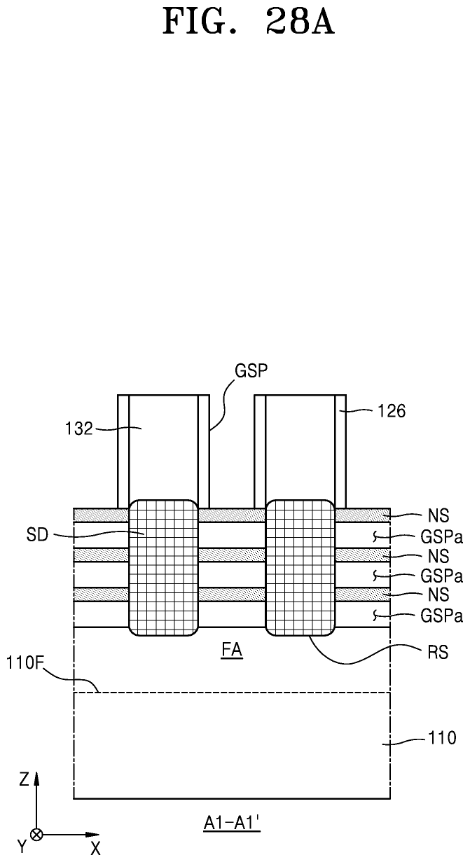

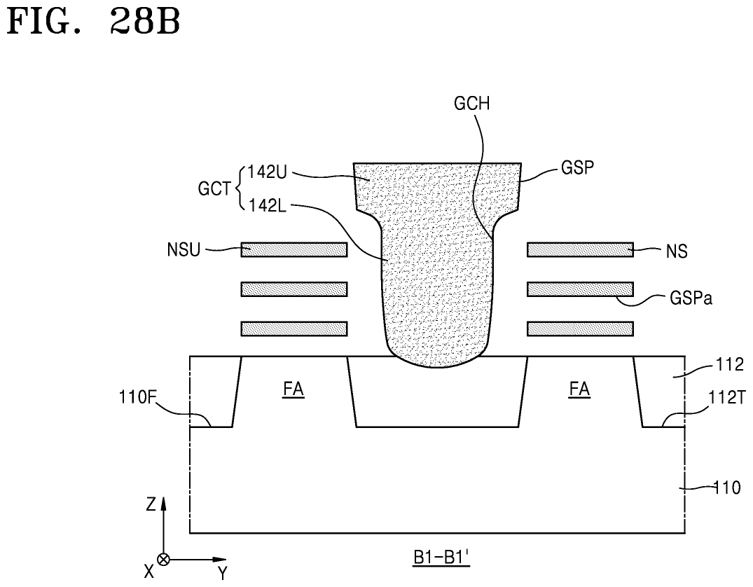

Referring to FIGS. 28A and 28B, the plurality of semiconductor patterns NS and the upper surface of the fin-type active region FA may be partially exposed by removing the plurality of sacrificial layers 210 remaining on the fin-type active region FA through the gate space GSP. A sub-gate space GSPa may be formed by extending the gate space GSP between the plurality of semiconductor patterns NS and between the lowermost semiconductor pattern NS and the fin-type active region FA. A process of removing the plurality of sacrificial layers 210 may include a wet etching process using a difference in etching selectivity between the sacrificial layer 210 and each of the plurality of semiconductor patterns NS.

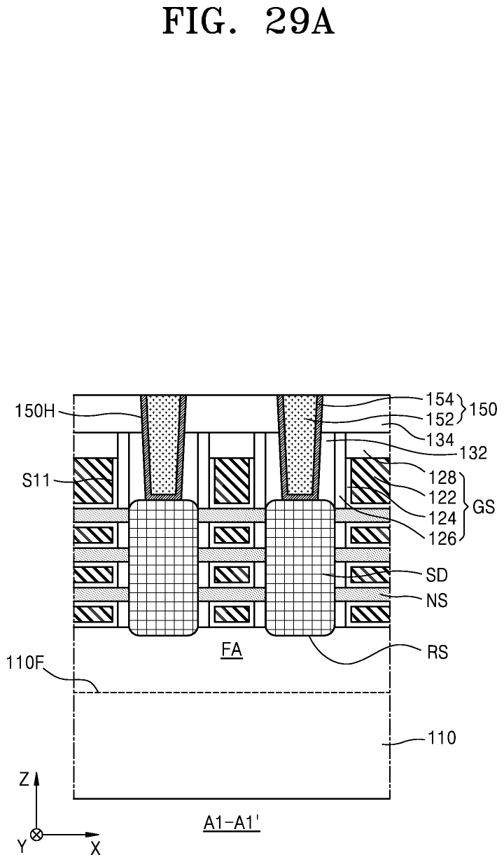

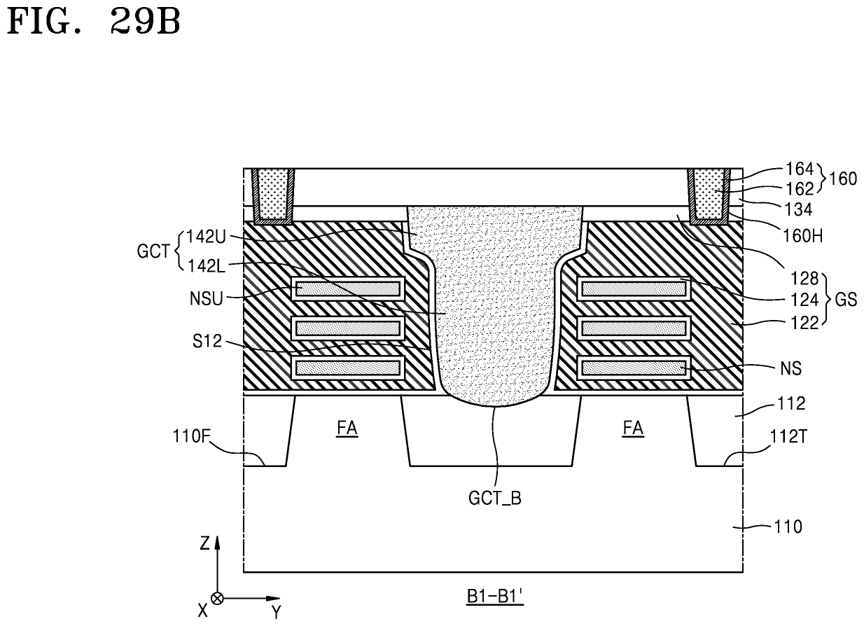

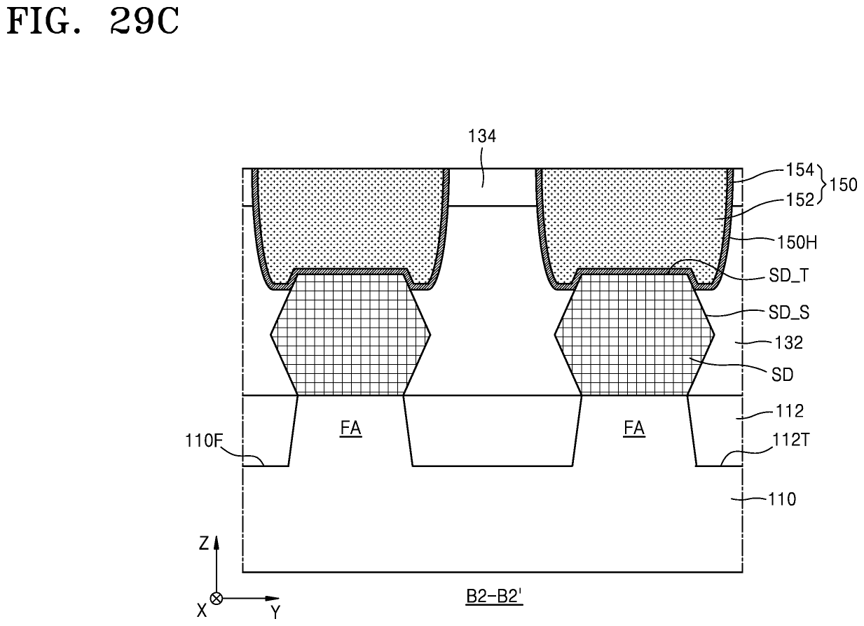

Referring to FIGS. 29A to 29C, the gate insulating layer 124 may be formed on surfaces exposed to the gate space GSP and the sub-gate space GSPa. In some embodiments, the gate electrode 122 filling the gate space GSP and the sub-gate space GSPa may be formed on the gate insulating layer 124. For example, the gate space GSP and the sub-gate space GSPa may be filled by conformally forming a work function conductive layer (not shown) on inner walls of the gate space GSP and the sub gate space GSPa, and subsequently forming a buried conductive layer (not shown) on the work function conductive layer. Alternatively or additionally, the gate electrode 122 may be formed by planarizing an upper portion of the buried conductive layer until the upper surface of the inter-gate insulating layer 132 is exposed.

In some embodiments, the work function control layer may include, but not be limited to, aluminum (Al), copper (Cu), titanium (Ti), tantalum (Ta), tungsten (W), molybdenum (Mo), tantalum nitride (TaN), nickel silicide (NiSi), cobalt silicide (CoSi), titanium nitride (TiN), tungsten nitride (WN), titanium aluminide (TiAl), titanium aluminum carbide (TiAlC), titanium aluminum nitride (TiAlN), tantalum carbonitride (TaCN), tantalum carbide (TaC), tantalum silicon nitride (TaSiN), or a combination thereof. The buried conductive layer may include, but not be limited to, aluminum (Al), copper (Cu), titanium (Ti), tantalum (Ta), tungsten (W), molybdenum (Mo), tantalum nitride (TaN), nickel silicide (NiSi), cobalt silicide (CoSi), titanium nitride (TiN), tungsten nitride (WN), titanium aluminide (TiAl), titanium aluminum carbide (TiAlC), titanium aluminum nitride (TiAlN), tantalum carbonitride (TaCN), tantalum carbide (TaC), tantalum silicon nitride (TaSiN), or a combination thereof.

In some embodiments, the gate electrode 122 and a part of an upper portion of the gate insulating layer 124 may be removed, and the gate capping layer 128 may be formed on the upper portion of the gate space GSP. Alternatively or additionally, the upper insulating layer 134 may be formed on the gate capping layer 128 and the inter-gate insulating layer 132.

The first contact hole 150H may be formed by forming a mask pattern (not shown) on the upper insulating layer 134, and removing a part of each of the upper insulating layer 134 and the inter-gate insulating layer 132 using the mask pattern as an etch mask. The first contact 150 may be formed by sequentially forming the conductive barrier layer 154 and the contact plug 152 in the first contact hole 150H.

In some embodiments, the second contact 160 may be formed by removing a part of each of the upper insulating layer 134 and the gate capping layer 128, forming the second contact hole 160H, and sequentially forming the conductive barrier layer 164 and the contact plug 162 inside the second contact hole 160H.

Referring back to FIGS. 3 to 5, the wiring structure WS including the first and second wiring layers ML1 and ML2 and the first and second vias VA1 and VA2 and the interlayer insulating layer 172 surrounding the wiring structure WS may be formed on the upper insulating layer 134.

In some embodiments, the integrated circuit device 100 may be formed through the process described above.

According to some embodiments, the gate cut insulating pattern GCT may be formed by forming the thick sacrificial insulating layer pattern 222 surrounding the plurality of semiconductor patterns NS and using the thick sacrificial insulating layer pattern 222 as a self-aligned mask. Therefore, a product defect that may be caused by the removal process of the sacrificial gate line 224, that may otherwise occur when the sacrificial gate line 224 is filled in a relatively narrow region between the gate cut insulating pattern GCT and the plurality of semiconductor patterns NS, may be prevented.

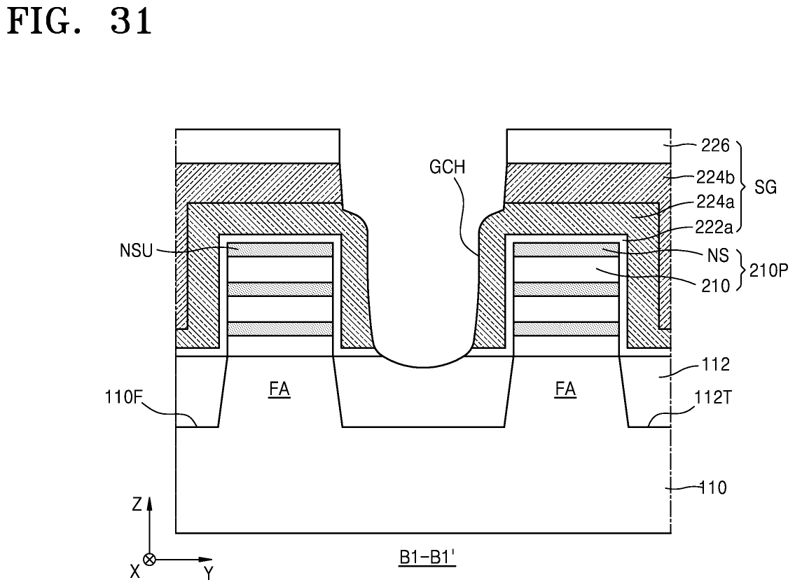

FIGS. 30 and 31 are cross-sectional views illustrating a manufacturing method of the integrated circuit device 100, according to some embodiments.

Referring to FIG. 30, a sacrificial gate structure SGa including a sacrificial insulating layer pattern 222a, a first sacrificial gate line 224a, a second sacrificial gate line 224b, and a sacrificial gate capping layer 226 may be formed on the channel semiconductor layer pattern 210P.

In some embodiments, the sacrificial insulating layer pattern 222a may be formed to a smaller thickness than the sacrificial insulating layer pattern 222, according to the manufacturing method described with reference to FIGS. 18 to 29C. For example, the sacrificial insulating layer pattern 222a may have a thickness less than or equal to 5 nm.

In some embodiments, the first sacrificial gate line 224a and the second sacrificial gate line 224b may include polysilicon. The first sacrificial gate line 224a may include a material having different etching characteristics from a material of the second sacrificial gate line 224b. In optional or additional embodiments, the first sacrificial gate line 224a may include polysilicon doped with a first impurity, and the second sacrificial gate line 224b may include polysilicon doped with a second impurity different from the first impurity. In other optional or additional embodiments, the first sacrificial gate line 224a may include polysilicon doped with the first impurity, and the second sacrificial gate line 224b may include undoped polysilicon. In some optional or additional embodiments, the first sacrificial gate line 224a may include undoped polysilicon, and the second sacrificial gate line 224b may include polysilicon doped with the first impurity. In other optional or additional embodiments, the first sacrificial gate line 224a may include polysilicon having a first density, and the second sacrificial gate line 224b may include polysilicon having a second density different from the first density.

In some embodiments, the gate cut opening GCH may be formed by removing the sacrificial gate capping layer 226 and the second sacrificial gate line 224b by performing the processes described with reference to FIGS. 20A to 22. The first sacrificial gate line 224a and the sacrificial insulating layer pattern 222a may remain on the bottom portion of the gate cut opening GCH, and the upper surface of the device isolation layer 112 may not be exposed to the bottom portion of the gate cut opening GCH.

In some embodiments, the first sacrificial gate line 224a may include a material having an etch selectivity with a material of the second sacrificial gate line 224b, and the first sacrificial gate line 224a may be partly removed or a relatively small amount thereof may be removed while the second sacrificial gate line 224b is removed at a relatively high etch rate. Accordingly, the first sacrificial gate line 224a may function as a self-aligned mask.

Referring to FIG. 31, a part of the first sacrificial gate line 224a and a part of the sacrificial insulating layer pattern 222a disposed on the bottom portion of the gate cut opening GCH may be further removed. In a removal process, the upper surface of the device isolation layer 112 may be exposed, and a part of the upper portion of the device isolation layer 112 may be removed together.

In some embodiments, the integrated circuit device 100 may be formed by performing the processes described with reference to FIGS. 24 to 29C.

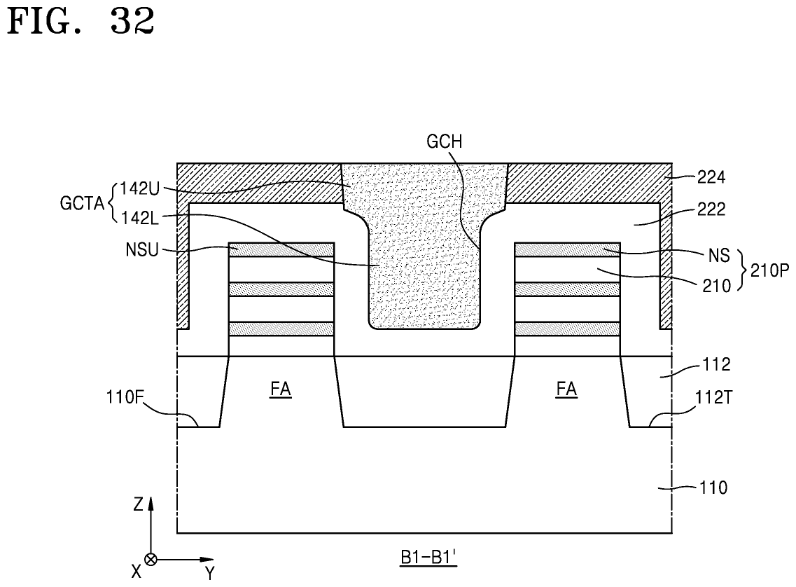

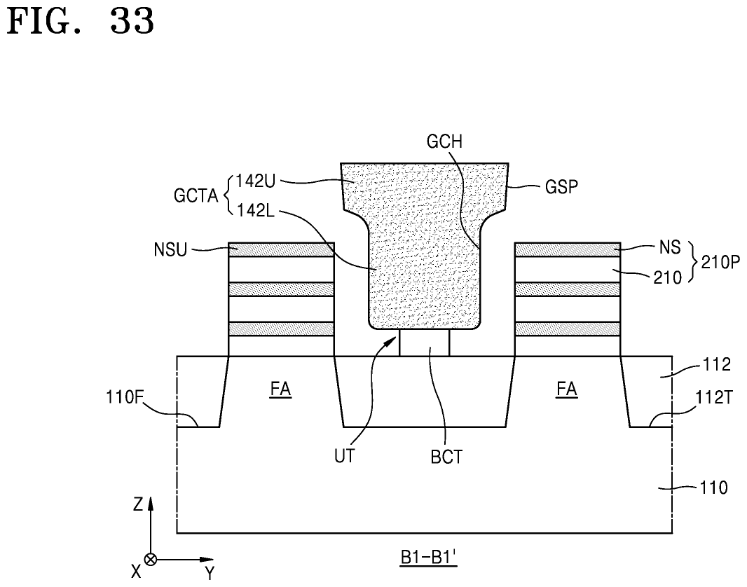

FIGS. 32 and 33 are cross-sectional views illustrating a method of manufacturing the integrated circuit device 100A, according to some embodiments.

First, the gate cut opening GCH may be formed by performing the processes described with reference to FIGS. 18 to 22 and removing the sacrificial gate capping layer 226 and the sacrificial gate line 224. The sacrificial insulating layer pattern 222 may remain on the bottom portion of the gate cut opening GCH, and the upper surface of the device isolation layer 112 may not be exposed to the bottom portion of the gate cut opening GCH.

Referring to FIG. 32, the gate cut insulating pattern GCTA filling the inside of the gate cut opening GCH may be formed. The gate cut insulating pattern GCTA may be disposed on the sacrificial insulating layer pattern 222 on the upper surface of the device isolation layer 112, and may be disposed between parts of the sacrificial insulating layer pattern 222 surrounding two adjacent channel semiconductor layer patterns 210P.

In some embodiments, the sacrificial gate capping layer 226 (e.g., as shown in FIG. 24) may be removed.

Referring to FIG. 33, the gate space GSP may be formed by sequentially removing the sacrificial gate line 224 and the sacrificial insulating layer pattern 222.

In some embodiments, in a process of removing the sacrificial insulating layer pattern 222 to form the gate space GSP, the sacrificial insulating layer pattern 222 disposed below the gate cut insulating pattern GCTA may not be completely removed, and a part of the sacrificial insulating layer pattern 222 may remain between the gate cut insulating pattern GCTA and the device isolation layer 112. In some embodiments, the part of the sacrificial insulating layer pattern 222 that may remain between the gate cut insulating pattern GCTA and the device isolation layer 112 may be referred to as the bottom insulating pattern BCT.

In some embodiments, the integrated circuit device 100A may be formed by performing the processes described with reference to FIGS. 28A to 29C.

While the present disclosure has been particularly shown and described with reference to embodiments thereof, it is to be understood that various changes in form and details may be made therein without departing from the spirit and scope of the following claims.

What is claimed is:

1. An integrated circuit device, comprising:
a substrate;
a fin-type active region on the substrate, the fin-type active region extending in a first direction;
a plurality of semiconductor patterns spaced apart from an upper surface of the fin-type active region and comprising a channel region;
a gate electrode extending in a second direction on the fin-type active region, disposed between the plurality of semiconductor patterns, and comprising a first sidewall extending in the second direction and a second sidewall extending in the first direction, the second direction intersecting with the first direction; and
a gate cut insulating pattern on the second sidewall of the gate electrode,
wherein an upper portion of the gate cut insulating pattern has a first width in the second direction,
wherein a lower portion of the gate cut insulating pattern has a second width in the second direction,
wherein the second width is smaller than the first width, and
wherein a portion of a sidewall of the gate cut insulating pattern is curved.

2. The integrated circuit device of claim 1, wherein the second sidewall of the gate electrode comprises a shoulder portion corresponding to the portion of the sidewall of the gate cut insulating pattern.

3. The integrated circuit device of claim 2, wherein:
an uppermost semiconductor pattern among the plurality of semiconductor patterns comprises a first side surface facing the gate cut insulating pattern, and
a first distance in a vertical direction between an upper surface of the uppermost semiconductor pattern and the shoulder portion of the second sidewall of the gate electrode is greater than or equal to approximately 80% and is smaller than or equal to approximately 120% of a second distance in the second direction between the first side surface of the uppermost semiconductor pattern and the shoulder portion of the second sidewall of the gate electrode.

4. The integrated circuit device of claim 3, wherein a third distance in the vertical direction between the upper surface of the uppermost semiconductor pattern and an upper surface of the gate electrode is greater than the first distance.

5. The integrated circuit device of claim 3, wherein:
the second distance is greater than or equal to approximately 5 nanometers (nm); and
the second distance is less than or equal to approximately 15 nm.

6. The integrated circuit device of claim 1, further comprising:
a gate insulating layer surrounding the first sidewall of the gate electrode, the second sidewall of the gate electrode, and a bottom surface of the gate electrode,
wherein the gate insulating layer is conformally disposed on a lower sidewall of the gate cut insulating pattern and an upper sidewall of the gate cut insulating pattern.

7. The integrated circuit device of claim 6, wherein:
the gate insulating layer is disposed between the gate electrode and the gate cut insulating pattern, and
the gate electrode is spaced apart from the gate cut insulating pattern.

8. The integrated circuit device of claim 1, further comprising:
an inter-gate insulating layer disposed on the substrate, on the first sidewall of the gate electrode, and on a sidewall of the gate cut insulating pattern.

9. The integrated circuit device of claim 1, further comprising:
a device isolation layer disposed on the substrate and a sidewall of the fin-type active region,
wherein a bottom surface of the gate cut insulating pattern is disposed on an upper surface of the device isolation layer.

10. The integrated circuit device of claim 1, further comprising:
a device isolation layer disposed on the substrate and a sidewall of the fin-type active region; and
a bottom insulating pattern between the device isolation layer and a bottom surface of the gate cut insulating pattern,
wherein a third width in the second direction of the bottom insulating pattern is smaller than the second width in the second direction of the lower portion of the gate cut insulating pattern.

11. An integrated circuit device, comprising:
a substrate;
a fin-type active region on the substrate, the fin-type active region extending in a first direction;
a plurality of semiconductor patterns spaced apart from an upper surface of the fin-type active region and comprising a channel region;
a gate electrode extending in a second direction on the fin-type active region, disposed between the plurality of semiconductor patterns, and comprising a shoulder portion extending outwardly in the second direction, the second direction intersecting with the first direction; and
a gate cut insulating pattern disposed on a first sidewall of the gate electrode, and comprising a stepped portion conforming to a shape of the shoulder portion.

12. The integrated circuit device of claim 11, wherein:
an upper portion of the gate cut insulating pattern has a first width in the second direction,
a lower portion of the gate cut insulating pattern has a second width in the second direction, and
the second width is smaller than the first width.

13. The integrated circuit device of claim 11, wherein
an uppermost semiconductor pattern among the plurality of semiconductor patterns comprises a first side surface facing the gate cut insulating pattern, and
a first distance in a vertical direction between an upper surface of the uppermost semiconductor pattern and the shoulder portion of the gate electrode is greater than or equal to approximately 80% and is less than or equal to approximately 120% of a second distance in the second direction between the first side surface of the uppermost semiconductor pattern and the shoulder portion of the gate electrode.

14. The integrated circuit device of claim 13, wherein a third distance in the vertical direction between the upper surface of the uppermost semiconductor pattern and an upper surface of the gate electrode is greater than the first distance.

15. The integrated circuit device of claim 11, further comprising:
a gate insulating layer surrounding the first sidewall of the gate electrode, a second sidewall of the gate electrode, and a bottom surface of the gate electrode; and
an inter-gate insulating layer disposed on the substrate, on the first sidewall of the gate electrode, and on a sidewall of the gate cut insulating pattern,
wherein the gate insulating layer is conformally disposed on the lower sidewall of the gate cut insulating pattern and on the upper sidewall of the gate cut insulating pattern.

16. The integrated circuit device of claim 15, wherein:
the gate insulating layer is disposed between the gate electrode and the gate cut insulating pattern, and
the gate electrode is spaced apart from the gate cut insulating pattern.

17. The integrated circuit device of claim 11, further comprising:
a device isolation layer disposed on the substrate and a sidewall of the fin-type active region,
wherein a bottom surface of the gate cut insulating pattern is disposed on an upper surface of the device isolation layer.

18. An integrated circuit device comprising:
a substrate;
a fin-type active region on the substrate, the fin-type active region extending in a first direction;
a device isolation layer disposed on the substrate and a sidewall of the fin-type active region;
a plurality of semiconductor patterns spaced apart from an upper surface of the fin-type active region and comprising a channel region;
a gate electrode extending in a second direction on the fin-type active region, disposed between the plurality of semiconductor patterns, and comprising a shoulder portion extending outwardly in the second direction, the second direction intersecting with the first direction;
a gate insulating layer surrounding a first sidewall extending in the second direction of the gate electrode, a second sidewall extending in the first direction of the gate electrode, and a bottom surface of the gate electrode;
a gate cut insulating pattern disposed on the second sidewall of the gate electrode, comprising a stepped portion conforming to a shape of the shoulder portion of the gate electrode, wherein a portion of the gate insulating layer is disposed between the stepped portion and the shoulder portion of the gate electrode; and
an inter-gate insulating layer on the substrate, on the first sidewall of the gate electrode, and on a sidewall of the gate cut insulating pattern.

19. The integrated circuit device of claim 18, wherein:
an upper portion of the gate cut insulating pattern has a first width in the second direction,
a lower portion of the gate cut insulating pattern has a second width in the second direction,
the second width is smaller than the first width, and
a portion of at least one of the lower sidewall of the gate cut insulating pattern and the upper sidewall of the gate cut insulating pattern is curved.

20. The integrated circuit device of claim 18, wherein:
an uppermost semiconductor pattern among the plurality of semiconductor patterns comprises a first side surface facing the gate cut insulating pattern,
a first distance in a vertical direction between an upper surface of the uppermost semiconductor pattern and the shoulder portion of the second sidewall of the gate electrode is greater than or equal to approximately 80% and is smaller than or equal to approximately 120% of a second distance in the second direction between the first side surface of the uppermost semiconductor pattern and the shoulder portion of the second sidewall of the gate electrode, and
a third distance in the vertical direction between the upper surface of the uppermost semiconductor pattern and an upper surface of the gate electrode is greater than the first distance.
